(19) United States
(12) Patent Application Publication
(10) Pub. No.: US 2013/0135264 A1
(43) Pub. Date: May 30, 2013

(54) MULTILAYER PIEZOELECTRIC THIN FILM RESONATOR STRUCTURE

(71) Applicant: Justin Phelps Black, Santa Clara, CA (US)

(72) Inventor: Justin Phelps Black, Santa Clara, CA (US)

(73) Assignee: QUALCOMM MEMS TECHNOLOGIES, INC., San Diego, CA (US)

(21) Appl. No.: 13/306,266

(22) Filed: Nov. 29, 2011

(51) Int. Cl. G09G 5/00; H03H 3/00; H03H 9/17

(52) U.S. Cl. 345/204; 333/187; 427/100; 216/13

(57) ABSTRACT

This disclosure provides implementations of electromechanical systems (EMS) resonator structures, devices, apparatus, systems and related processes. In one aspect, a resonator structure includes a lower conductive layer of electrodes; a lower piezoelectric layer; a middle conductive layer of electrodes; an upper piezoelectric layer; and an upper conductive layer of electrodes. In one aspect, a first arrangement of the electrodes includes a first-type drive electrode in the lower conductive layer, a second-type drive electrode in the middle conductive layer, and a first-type drive electrode in the upper conductive layer; a second arrangement of the electrodes includes a second-type drive electrode in the lower conductive layer, a first-type drive electrode in the middle conductive layer, and a second-type drive electrode in the upper conductive layer; the first-type drive electrodes are coupled to receive a first input signal; and the second-type drive electrodes are coupled to receive a second input signal.

### TECHNICAL FIELD

This disclosure relates generally to electromechanical systems resonators, and more specifically to multilayer piezoelectric thin film contour mode resonator (CMR) structures.

### DESCRIPTION OF THE RELATED TECHNOLOGY

Electromechanical systems (EMS) include devices having electrical and mechanical elements, transducers such as actuators and sensors, optical components (including mirrors), and electronics. Electromechanical systems can be manufactured at a variety of scales including, but not limited to, microscales and nanoscales. For example, microelectromechanical systems (MEMS) devices can include structures having sizes ranging from about one micron to hundreds of microns or more. Nanoelectromechanical systems (NEMS) devices can include structures having sizes smaller than one micron including, for example, sizes smaller than several hundred nanometers. Electromechanical elements may be created using deposition, etching, lithography, and/or other micromachining processes that etch away parts of substrates and/or deposited material layers, or that add layers to form electrical, mechanical, and electromechanical devices.

One type of EMS device is called an interferometric modulator (IMOD). As used herein, the term IMOD or interferometric light modulator refers to a device that selectively absorbs and/or reflects light using the principles of optical interference. In some implementations, an IMOD may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the IMOD. IMOD devices have a wide range of applications, and are anticipated to be used in improving existing products and creating new products, especially those with display capabilities.

Various electronic circuit components can be implemented at the EMS level, including resonators. Some conventional resonator structures provide less than desirable electrical and mechanical energy conversion. In some resonator designs, the efficiency of this electromechanical coupling is based on the effectiveness of translation of electrical energy, from an input electrical signal delivered to an input terminal, to mechanical motion of a piezoelectric material that is translated back to electrical energy at the input terminal or an output terminal. Conventional resonator devices having poor electromechanical coupling can have sub-optimal operational efficiency and signal throughput.

Some conventional resonator devices produce and sense electric fields across the thickness of the piezoelectric layer. These configurations do not couple well to two-dimensional Lamb wave strain fields at high (e.g., GHz) frequencies and exhibit relatively small electromechanical coupling coefficient (kₜ²) values that limit filter fractional bandwidth and insertion loss.

### SUMMARY

The structures, devices, apparatus, systems, and processes of the disclosure each have several innovative aspects, no single one of which is solely responsible for the desirable attributes disclosed herein.

Disclosed are example implementations of electromechanical systems resonator structures, such as contour mode resonators (CMR), devices, apparatus, systems, and related fabrication processes.

According to one innovative aspect of the subject matter described in this disclosure, a resonator structure includes a lower conductive layer of electrodes; a lower piezoelectric layer disposed on the lower conductive layer; a middle conductive layer of electrodes disposed on the lower piezoelectric layer opposite the lower conductive layer; an upper piezoelectric layer disposed on the middle conductive layer opposite the lower piezoelectric layer; and an upper conductive layer of electrodes disposed on the upper piezoelectric layer opposite the middle conductive layer. In some implementations, a first arrangement of the electrodes is located at a first position along a width of the structure and generally aligned along a thickness of the structure, the first arrangement including a first-type drive electrode in the lower conductive layer, a second-type drive electrode in the middle conductive layer, and a first-type drive electrode in the upper conductive layer. In some implementations, a second arrangement of the electrodes is located at a second position along the width and generally aligned along the thickness, the second arrangement including a second-type drive electrode in the lower conductive layer, a first-type drive electrode in the middle conductive layer, and a second-type drive electrode in the upper conductive layer. In some implementations, the first-type drive electrodes are coupled to receive a first input signal and the second-type drive electrodes are coupled to receive a second input signal.

In some implementations, the first arrangement and the second arrangement are periodically repeated at least once along the width such that there are at least two instances of the first arrangement and at least two instances of the second arrangement and such that each instance of the first arrangement is separated by an adjacent instance of the first arrangement by an instance of the second arrangement, and vice versa. In some such implementations, a center-to-center distance from each electrode to its closest neighbor electrode along the same conductive layer is substantially equal to half of the acoustic wavelength, λ, of the structure, and a center-to-center distance from each electrode to the next electrode of the same type along the same conductive layer is substantially equal to λ.

In some implementations, the resonator structure further includes a third arrangement of the electrodes located at a third position along the width and generally aligned along the thickness, the third arrangement including a first-type signal electrode in the lower conductive layer, a second-type signal electrode in the middle conductive layer, and a first-type signal electrode in the upper conductive layer. In some such implementations, the first-type signal electrodes are coupled to output an output signal.

In some implementations, the electrodes in the middle conductive layer in the first and second arrangements each have a width that is substantially greater than that of each of the respective overlying or underlying electrodes of the upper and lower conductive layers.

Another innovative aspect of the subject matter described in this disclosure can be implemented in a process for forming a resonator structure. In some implementations, the process includes: forming a lower conductive layer of electrodes; forming a lower piezoelectric layer over the lower electrode layer; forming a middle conductive layer of electrodes over the lower piezoelectric layer; forming an upper piezoelectric layer over the middle conductive layer; and forming an upper conductive layer of electrodes over the upper piezoelectric layer. In some implementations, the described layers are arranged such that a first arrangement of the electrodes is located at a first position along a width of the structure and generally aligned along a thickness of the structure, the first arrangement including a first-type drive electrode in the lower conductive layer, a second-type drive electrode in the middle conductive layer, and a first-type drive electrode in the upper conductive layer. In some implementations, the described layers are arranged such that a second arrangement of the electrodes is located at a second position along the width and generally aligned along the thickness, the second arrangement including a second-type drive electrode in the lower conductive layer, a first-type drive electrode in the middle conductive layer, and a second-type drive electrode in the upper conductive layer. In some implementations, the first-type drive electrodes are coupled to receive a first input signal and the second-type drive electrodes are coupled to receive a second input signal.

In some implementations, forming the lower conductive layer of electrodes includes forming the lower conductive layer of electrodes over a sacrificial layer. In some such implementations, the process can further include forming the sacrificial layer on a substrate prior to forming the lower conductive layer of electrodes over the sacrificial layer; and removing at least a portion of the sacrificial layer to define a cavity such that at least a substantial portion of the lower electrode layer is spaced apart from the substrate.

Another innovative aspect of the subject matter described in this disclosure can be implemented in a method for using a resonator structure. The method can include: providing a piezoelectric resonator structure; applying a first input signal to the first-type drive electrodes; and applying a second input signal to the second-type drive electrodes. In some implementations, applying the first and second input signals causes one or more modes of vibration in the piezoelectric resonator structure.

In some implementations, the piezoelectric resonator structure further includes a third arrangement of the electrodes located at a third position along the width and generally aligned along the thickness, the third arrangement including a first-type signal electrode in the lower conductive layer, a second-type signal electrode in the middle conductive layer, and a first-type signal electrode in the upper conductive layer. In some such implementations, the method can further include: sensing, using the third arrangement of electrodes, displacements associated with the d₃₃ piezoelectric field component resulting from vibrations caused by vertical and lateral electric field components resulting from the applied first and second input signals; and outputting an output signal based on the sensing.

Another innovative aspect of the subject matter described in this disclosure can be implemented in apparatus including first conductive means of electrodes; first piezoelectric means including a first piezoelectric material disposed over the first conductive means of electrodes; second conductive means of electrodes disposed over the first piezoelectric means opposite the first conductive means of electrodes; second piezoelectric means including a second piezoelectric material disposed over the second conductive means of electrodes opposite the first piezoelectric means; and third conductive means of electrodes disposed over the second piezoelectric means opposite the second conductive means of electrodes; first coupling means; and second coupling means. In some implementations, a first arrangement of the electrodes is located at a first position along a width of the structure and generally aligned along a thickness of the structure, the first arrangement including a first-type drive electrode in the first conductive means, a second-type drive electrode in the second conductive means, and a first-type drive electrode in the third conductive means. In some implementations, a second arrangement of the electrodes is located at a second position along the width and generally aligned along the thickness, the second arrangement including a second-type drive electrode in the first conductive means, a first-type drive electrode in the second conductive means, and a second-type drive electrode in the third conductive means. In some such implementations, the first-type drive electrodes are coupled to receive a first input signal via the first coupling means and the second-type drive electrodes are coupled to receive a second input signal via the second coupling means.

Details of one or more implementations of the subject matter described in this specification are set forth in the accompanying drawings and the description below. Although the examples provided in this disclosure are primarily described in terms of electromechanical systems (EMS) and microelectromechanical systems (MEMS)-based displays, the concepts provided herein may apply to other types of displays, such as liquid crystal displays, organic light-emitting diode (“OLED”) displays and field emission displays. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A shows a cross-sectional side view of an example of a resonator such as a contour mode resonator (CMR).

FIG. 1B shows a cross-sectional side view of an example of a resonator.

FIG. 2 shows a cross-sectional side view of an example of a CMR piezoelectric layer showing approximate particle displacements for an example Lamb-wave-mode.

FIG. 3 shows an example of a CMR topology employing a common ground excitation (CGE) electrode scheme.

FIG. 4A shows an example of a CMR topology employing a differential ground excitation (DGE) electrode scheme.

FIG. 4B shows an example of a CMR topology employing a DGE electrode scheme and two piezoelectric layers.

FIG. 5 shows a cross-sectional side view of an example CMR piezoelectric layer showing approximate particle displacements for an example 2 GHz S₀ Lamb-wave-mode.

FIG. 6 shows a perspective view of an example CMR device.

FIG. 7A shows a cross-sectional side view of a portion of an example implementation of the CMR device of FIG. 6.

FIG. 7B shows example approximate particle displacements for the topology of FIG. 7A.

FIG. 8A shows example vertical electric fields created in, for example, the CMR of FIG. 7A.

FIG. 8B shows example lateral electric fields created in, for example, the CMR of FIG. 7A.

FIG. 9 shows a cross-sectional side view of an example CMR having a topology similar to that of the CMR of FIG. 7A along with corresponding example approximate particle displacements.

FIG. 10 shows a cross-sectional side view of another example CMR that includes additional sensing output ports, along with corresponding example approximate particle displacements.

FIG. 11A shows a top view of an example contour mode resonator (CMR) device.

FIG. 11B shows a bottom view of the CMR device of FIG. 11A.

FIG. 11C shows a hidden view of a middle layer in the CMR device of FIG. 11A.

FIG. 12A shows a top view of another example CMR device.

FIG. 12B shows a bottom view of the CMR device of FIG. 12A.

FIG. 12C shows a hidden view of a middle layer in the CMR device of FIG. 12A.

FIG. 13 shows a perspective cross-sectional view of an example CMR device, such as that shown in FIG. 6.

FIG. 14 shows a top view of an example resonator device.

FIG. 15A shows a perspective cross-sectional view of an example two-port resonator structure, such as, for example, an implementation of the two-port resonator structure of FIG. 10.

FIG. 15B shows a top view of the example two-port resonator structure of FIG. 15A.

FIG. 16 shows a flow diagram illustrating an example process for forming an example resonator structure.

FIG. 17 shows a flow diagram illustrating an example process for forming an example staggered resonator structure.

FIGS. 18A-18I show cross-sectional schematic illustrations of example stages of staggered resonator fabrication in an example process, for instance, as represented in FIG. 16 or FIG. 17.

FIGS. 19A-19I show perspective views of example stages of staggered resonator fabrication in an example process, for instance, as represented in FIG. 16 or FIG. 17.

FIG. 20A shows an isometric view depicting two adjacent example pixels in a series of pixels of an example interferometric modulator (IMOD) display device.

FIG. 20B shows an example system block diagram illustrating an example electronic device incorporating an interferometric modulator display.

FIGS. 21A and 21B show examples of system block diagrams illustrating an example display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied and implemented in a multitude of different ways.

The disclosed implementations include examples of structures and configurations of electromechanical systems resonator devices, including contour mode resonators (CMR). Related apparatus, systems, and fabrication processes and techniques are also disclosed. CMRs are referred to as “contour mode” because of their substantially lateral in-plane modes of vibration, as described in greater detail below. In the case of piezoelectric resonators, electrodes are generally disposed in contact with or in proximity to a piezoelectric material. For instance, the electrodes can be located on the same surface or on opposite surfaces of a layer of the piezoelectric material.

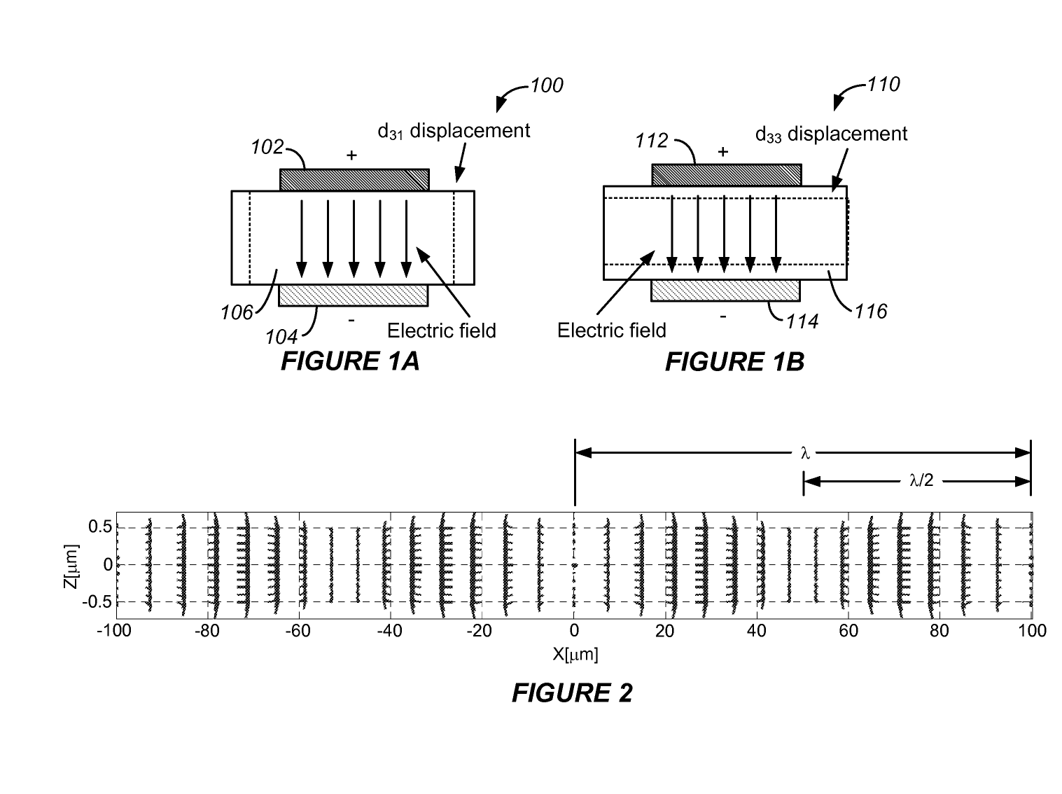

FIG. 1A shows a cross-sectional side view of an example of a resonator such as a contour mode resonator (CMR). In FIG. 1A, the CMR 100 includes a first electrode 102, a second electrode 104, and a piezoelectric layer 106 sandwiched between the first electrode 102 and the second electrode 104. The CMR 100 is configured to have lateral deformation and displacement in accordance with the d₃₁ piezoelectric coefficient. FIG. 1B shows a cross-sectional side view of an example of a resonator. In FIG. 1B, the resonator 110 includes a first electrode 112, a second electrode 114, and a piezoelectric layer 116 sandwiched in between the first electrode 112 and the second electrode 114. FIG. 1B shows the thickness component of deformation and displacement of the piezoelectric layer 116 in accordance with the d₃₃ piezoelectric coefficient.

An electric field applied between first and second electrodes in FIG. 1A or 1B is transduced into a mechanical strain in the piezoelectric material. For instance, a time-varying electrical signal can be provided to an input electrode of the CMR and transduced to a corresponding time-varying mechanical motion. A portion of this mechanical energy can be transferred back to electrical energy at the input electrode or at a separate output electrode. The frequencies of the input electrical signal that produce the greatest substantial amplifications of the mechanical displacement in the piezoelectric material are generally referred to as resonant frequencies of the CMR.

The electromechanical coupling coefficient, kₜ², is a property of a resonator that determines the bandwidth and insertion loss of, for example, a filter incorporating the resonator. The kₜ² value of some CMRs is limited by the d₃₁ piezoelectric coefficient, which is typically about a factor of 3 smaller than the d₃₃ coefficient associated with film bulk acoustic resonators (FBAR) and bulk acoustic wave (BAW) resonators. For reference, FIG. 1A illustrates the in-plane strain or displacement associated with the d₃₁ piezoelectric coefficient as a result of a vertical out-of-plane electric field (represented by the arrows) applied between electrodes 102 and 104, while FIG. 1B illustrates the out-of-plane (orthogonal) strain or displacement associated with the d₃₃ piezoelectric coefficient as a result of a vertical out-of-plane electric field (represented by the arrows) applied between electrodes 112 and 114.

Many higher frequency CMRs employ Lamb wave modes of vibration. A Lamb wave consists of a superposition of transverse (out-of-plane) and longitudinal (in-plane) components, where the relative amplitude of each component varies as a function of the ratio of the piezoelectric layer thickness, d, to acoustic wavelength, λ. For the first order symmetric mode, S₀, at frequencies of a few hundred MHz or less, where the ratio of d/λ is small (such as around 0.01), the amplitude of the longitudinal component is much greater than the transverse component, and piezoelectric layer motion is thus predominantly in the plane of the substrate.

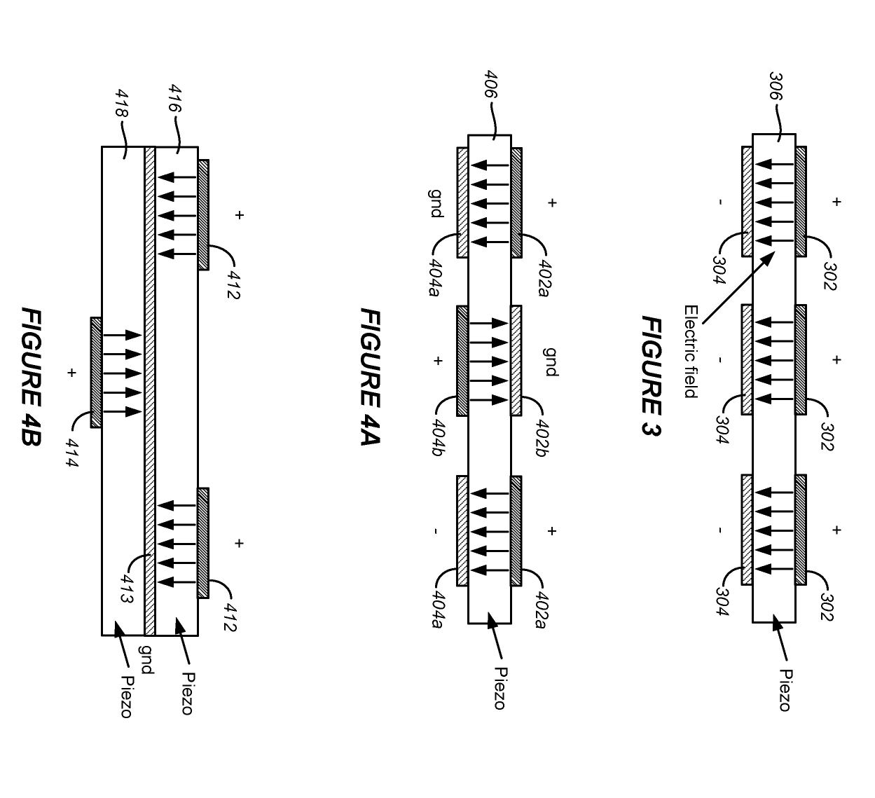

FIG. 2 shows a cross-sectional side view of an example of a CMR piezoelectric layer showing approximate particle displacements for an example Lamb-wave-mode. In FIG. 2, the piezoelectric layer (not to scale) shows the approximate particle displacement for a 100 MHz S₀ Lamb-wave-mode CMR where d=1 μm and λ=100 μm (where the distances along the X and Z axes are measured from a central axis at the center of the CMR). As shown, the particle displacement and strain is primarily in the plane of the resonator.

Some CMR electrode topologies generate vertical electric fields across the thickness of the piezoelectric layer and excite lateral deformation through the d₃₁ piezoelectric coefficient. FIG. 3 shows an example of a CMR topology employing a common ground excitation (CGE) electrode scheme. As shown in FIG. 3, the upper layer electrodes 302 are equipotential (e.g., connected to a common positive input signal) while the lower layer electrodes 304 are equipotential (e.g., connected to a common negative input signal) resulting in a vertical electric field (represented by the arrows) across the piezoelectric layer 306.

FIG. 4A shows an example of a CMR topology employing a differential ground excitation (DGE) electrode scheme. FIG. 4B shows an example of a CMR topology employing a DGE electrode scheme and two piezoelectric layers. In contrast to the configuration shown in FIG. 3, in FIG. 4A the potentials supplied to the upper layer electrodes 402a and 402b alternate, for example, between a positive input signal and ground. Similarly, the lower layer electrodes 404a and 404b alternate between, for example, ground and a positive input signal such that periodically alternating vertical electric fields (represented by the arrows) are generated across the piezoelectric layer 406. In FIG. 4B, the DGE configuration includes an upper layer of electrodes 412, a lower layer of electrodes 414, and an intermediate ground plane 413 arranged between an upper piezoelectric layer 416 and a lower piezoelectric layer 418. In this configuration, the upper layer electrodes 412 and lower layer electrodes 414 can be connected to a common (e.g., positive) input signal while the intermediate plane 413 is grounded. Again, as with the example configurations of FIGS. 3 and 4A, the applied electric fields in the CMR configuration shown in FIG. 4B are essentially one-dimensional, namely, orthogonal to the plane of the resonator and the substrate.

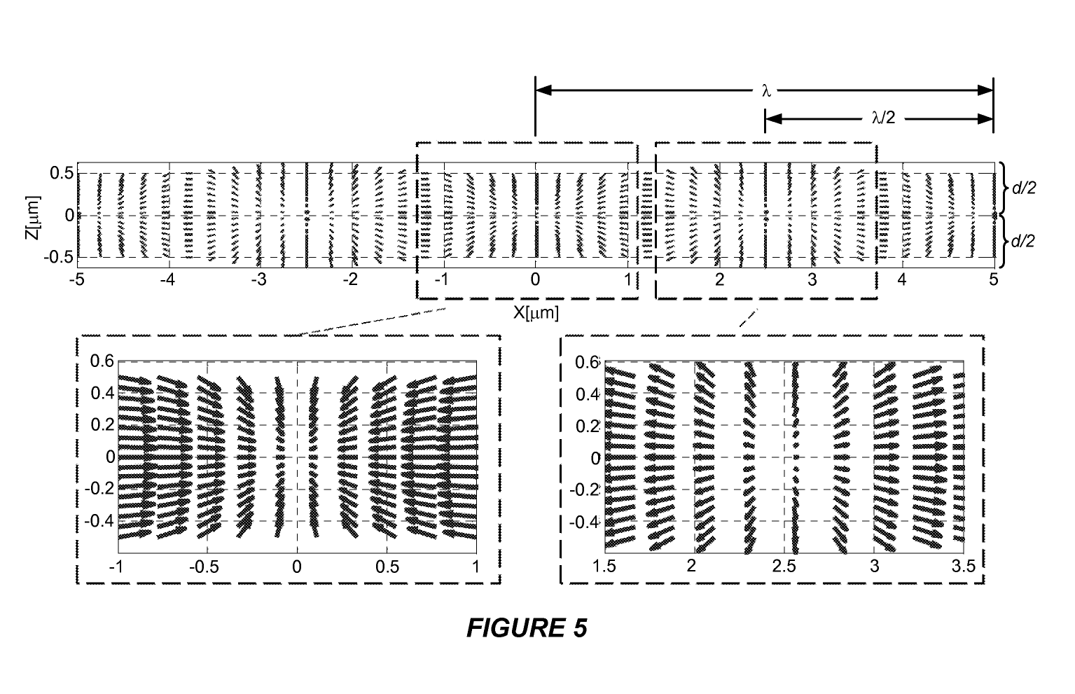

In the configurations shown in FIGS. 3, 4A and 4B, the CMRs can produce and sense electric fields across the thickness of the piezoelectric layers; that is, the resonators excite and sense vibration through the displacement associated with the d₃₁ piezoelectric coefficient. These configurations may not couple well to the two-dimensional Lamb wave strain fields at high (e.g., GHz) frequencies and may exhibit relatively small kₜ² values that limit filter fractional bandwidth and insertion loss. The drive electric displacement fields and sense polarization fields are largely one-dimensional. For a ratio d/λ at high (e.g., GHz and beyond) frequencies, the transverse component increases and the strain becomes two-dimensional as shown in FIG. 5. FIG. 5 shows a cross-sectional side view of an example CMR piezoelectric layer showing approximate particle displacements for an example 2 GHz S₀ Lamb-wave-mode. In particular, the resonator piezoelectric layer of FIG. 5 (not to scale) shows the approximate particle displacement for a 2 GHz S₀ Lamb-wave-mode CMR where d=1 μm and λ=5 μm. As shown, there is a substantial vertical component associated with the mode, and its amplitude increases as the ratio of d/λ increases.

While there may be regions of lateral motion at odd quarter-wavelength intervals in the examples above, there also may be alternating regions of predominantly vertical displacement. Furthermore, both transverse and longitudinal components may be symmetric about the thickness of the piezoelectric layer. CGE and DGE topologies can be less efficient at exciting the high frequency S₀ mode since the electric field emanating from the electrodes is generally misaligned to the strain and polarization fields, and at some positions, is completely 180 degrees out of phase. The afore-described single- and two-piezoelectric layer CGE and DGE topologies fail to account both for symmetry in the strain across the thickness of the piezoelectric layer and for the transverse displacement. This may explain the decrease in kₜ² that has been observed with some conventional CMR structures at higher frequencies.

Particular implementations of the subject matter described in this disclosure include two piezoelectric layers and patterned lower, middle, and upper electrode layers configured to utilize the symmetry and transverse displacement inherent at high (e.g., GHz) frequencies. Some example implementations include a CMR that efficiently couples to GHz S₀ Lamb waves. In such implementations, the resonator transduces vibration through displacement associated with both the d₃₁ and the d₃₃ piezoelectric coefficients, resulting in a higher kₜ² than can be achieved in traditional topologies that only drive and sense vibration through displacement associated with the d₃₁ coefficient. In particular implementations, an example CMR device includes an upper conductive layer of first electrodes and second electrodes. The first electrodes are coupled to a first port and the second electrodes are coupled to a second port. A middle conductive layer of electrodes is situated underneath the upper conductive layer of electrodes on the opposite side of an upper piezoelectric layer. A lower piezoelectric layer is situated below the middle conductive layer. A lower conductive layer of electrodes is situated underneath the middle conductive layer of electrodes on the opposite side of the lower piezoelectric layer. In some implementations, the middle conductive layer includes a similar arrangement of first electrodes underlying the first electrodes of the upper conductive layer and coupled to the second port. In such an implementation, the middle conductive layer also includes a similar arrangement of second electrodes underlying the second electrodes of the upper conductive layer and coupled to the first port. In some implementations, the lower conductive layer includes a similar arrangement of first electrodes underlying the first electrodes of the upper conductive layer and coupled to the first port and a similar arrangement of second electrodes underlying the second electrodes of the upper conductive layer and coupled to the second port.

Particular implementations of the subject matter described in this disclosure can be implemented to realize one or more of the following potential advantages. By taking advantage of the strain/displacement associated with the d₃₃ piezoelectric coefficient, the Q and kₜ² of the desired modes can be enhanced. The proposed solutions can produce CMRs with larger kₜ² values since the transduction schemes utilize the strains associated with both the d₃₁ and d₃₃ piezoelectric coefficients. A larger kₜ² value results in, for example, filters with lower insertion loss and wider bandwidth.

Some implementations described herein are based on a contour mode resonator configuration. In such implementations, the resonant frequency of a CMR can be substantially controlled by engineering the lateral (e.g., length and width) dimensions of the piezoelectric material layers and the electrode layers as well as engineering the periodicity of the electrodes and the thickness of the piezoelectric layer. One benefit of such a construction is that multi-frequency RF filters, clock oscillators, transducers or other devices, each including one or more CMRs depending on the desired implementation, can be fabricated on the same substrate. For example, this may be advantageous in terms of cost and size by enabling compact, multi-band filter solutions for RF front-end applications on a single chip. In some examples, by co-fabricating multiple CMRs with different finger widths, as described in greater detail below, multiple frequencies can be addressed on the same die. In some examples, arrays of CMRs with different frequencies spanning a range from MHz to GHz can be fabricated on the same substrate.

Furthermore, with the disclosed CMRs, direct frequency synthesis for spread spectrum communication systems can be enabled by multi-frequency narrowband filter banks including high quality factor (Q) resonators, without the need for phase-locked loops (PLLs). The disclosed CMR implementations can provide for piezoelectric transduction with low motional resistance while maintaining high Q values and appropriate reactance values that facilitate their interface with contemporary circuitry. Some examples of the disclosed laterally vibrating resonator structures provide the advantages of compact size, e.g., on the order of 100 um (micrometers) in length and/or width, low power consumption, and compatibility with high-yield mass-producible components.

In one or more implementations of the disclosed CMRs, the resonator structure is suspended in a cavity of a supporting structure. The resonator structure can be suspended in the cavity by specially designed tethers coupling the resonator structure to the supporting structure, as further explained below. These tethers are often fabricated in the layer stack of the resonator structure itself. The resonator structure can be acoustically isolated from the surrounding structural support and other apparatus by virtue of the cavity.

The disclosed resonator structures can be fabricated on a low-cost, high-performance, large-area insulating substrate, which, in some implementations, forms at least a portion of the supporting structure described herein. In some implementations, the insulating substrate on which the disclosed resonator structures are formed can be made of display-grade glass (alkaline earth boro-aluminosilicate) or soda lime glass. Other suitable insulating materials of which the insulating substrate can be made include silicate glasses, such as alkaline earth aluminosilicate, borosilicate, modified borosilicate, and others. Also, ceramic materials such as aluminum oxide (AlOx), yttrium oxide (Y₂O₃), boron nitride (BN), silicon carbide (SiC), aluminum nitride (AlNx), and gallium nitride (GaNx) can be used as the insulating substrate material. In some other implementations, the insulating substrate is formed of high-resistivity silicon. In some implementations, silicon-on-insulator (SOI) substrates, gallium arsenide (GaAs) substrates, indium phosphide (InP) substrates, and plastic (polyethylene naphthalate or polyethylene terephthalate) substrates, e.g., associated with flexible electronics, also can be used. The substrate can be in conventional Integrated Circuit (IC) wafer form, e.g., 4-inch, 6-inch, 8-inch, 12-inch, or in large-area panel form. For example, flat panel display substrates with dimensions such as 370 mm×470 mm, 920 mm×730 mm, and 2850 mm×3050 mm, can be used.

In some implementations, the disclosed resonator structures are fabricated by depositing a sacrificial (SAC) layer on the substrate; forming one or more lower (first) electrode layers on the SAC layer; depositing a lower (first) piezoelectric layer on the lower electrode layer; forming one or more middle (second) electrode layers on the lower piezoelectric layer; forming an upper (second) piezoelectric layer on the middle electrode layer; forming one or more upper (third) electrode layers on the upper piezoelectric layer; and removing at least part of the SAC layer to define a cavity. The resulting resonator cavity separates at least a portion of the lower electrode layer from the substrate and provides openings along the sides of the resonator structure, as illustrated in the accompanying figures, to allow the resonator to vibrate and move in one or more directions with substantial elastic isolation from the remaining substrate. In some other implementations, a portion of the substrate itself serves as a SAC material. In these implementations, designated regions of the insulating substrate below the resonator structure can be removed, for example, by etching to define the cavity.

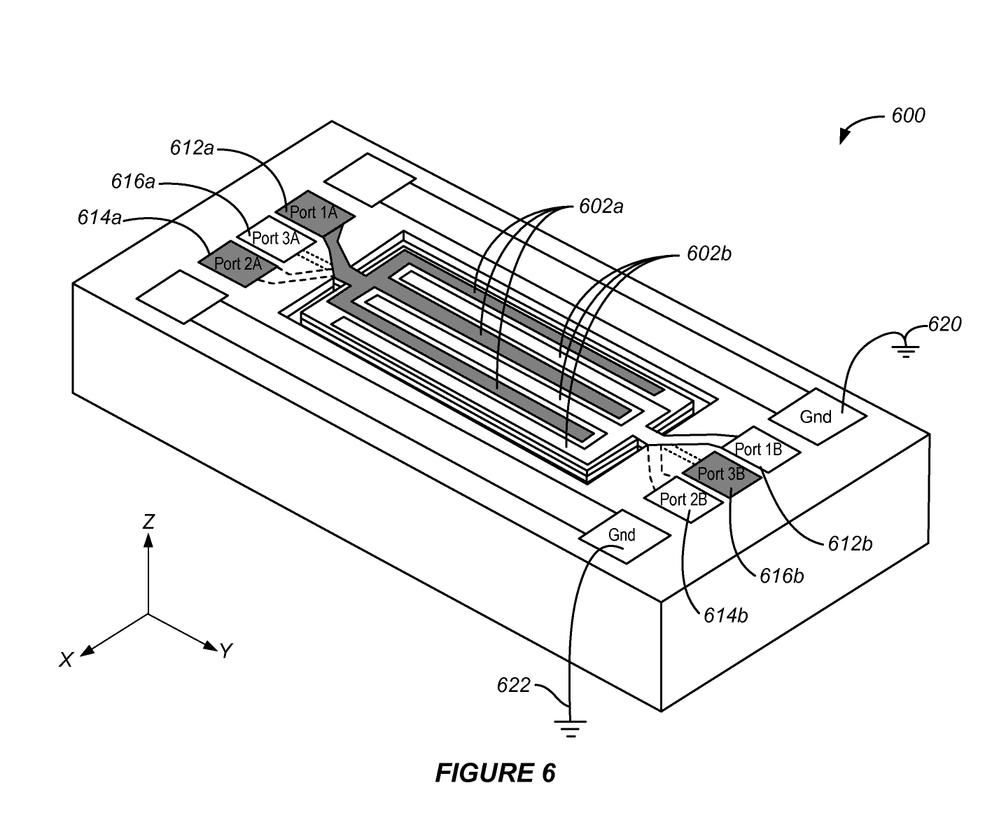

FIG. 6 shows a perspective view of an example CMR device. In FIG. 6, CMR structure 600 includes an upper conductive layer of electrodes 602a and 602b. The first electrodes 602a are connected to a first port 612a, referred to as “Port 1A.” The second electrodes 602b are connected to a second port 612b, referred to as “Port 1B.” A lower conductive layer of electrodes (not shown) is situated underneath the upper conductive layer of electrodes 602a and 602b on the opposite side of a set of lower and upper piezoelectric layers 608 and 610, which themselves have a middle conductive layer of electrodes patterned in between, as described below. In one example implementation, the lower conductive layer includes a similar arrangement of first electrodes 604a underlying the first electrodes 602a of the upper conductive layer and connected to a port 614a, referred to as “Port 2A,” and a similar arrangement of second electrodes 604b underlying the second electrodes 602b of the upper conductive layer and connected to a port 614b, referred to as “Port 2B.” In one example implementation, the middle conductive layer includes a similar arrangement of first electrodes 606a underlying the first electrodes 602a of the upper conductive layer and connected to a port 616a, referred to as “Port 3A,” and a similar arrangement of second electrodes 606b underlying the second electrodes 602b of the upper conductive layer and connected to a port 616b, referred to as “Port 3B.”

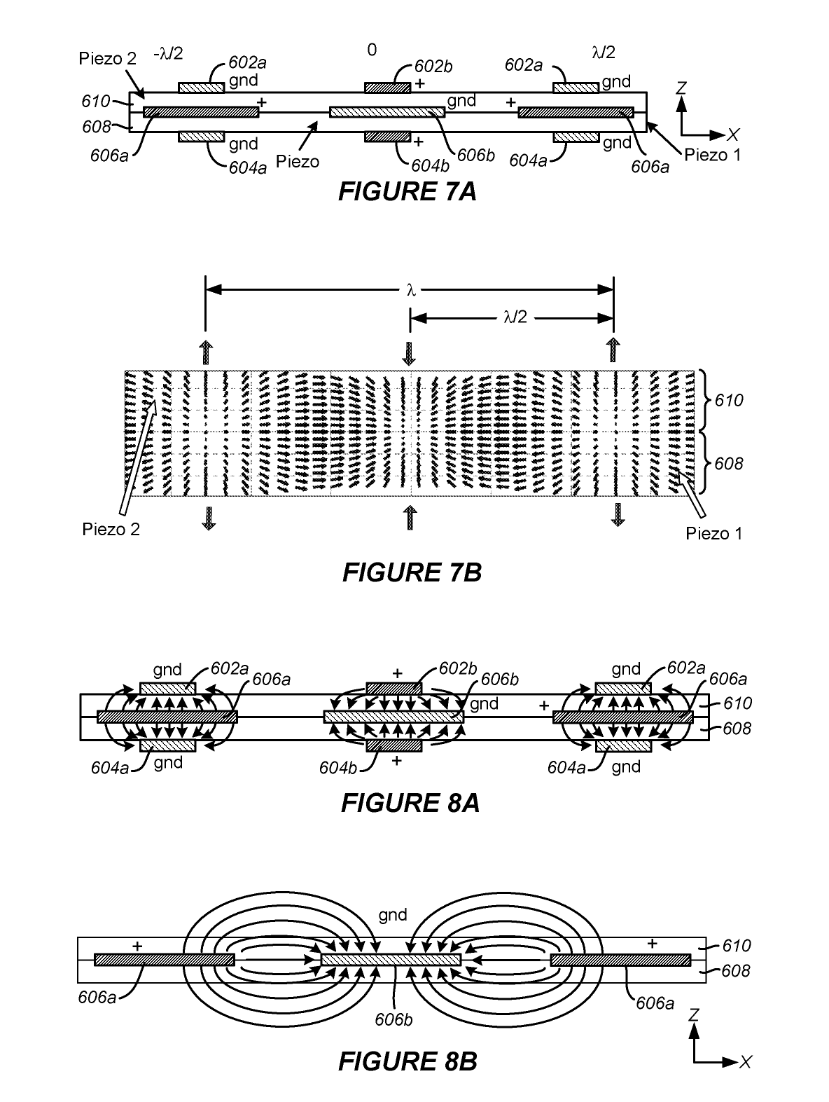

FIG. 7A shows a cross-sectional side view of a portion of an example implementation of the CMR 600 of FIG. 6. In FIG. 7A, as further described below, the ports 612a, 612b, 614a, 614b, 616a, and 616b can have different configurations. In the example configuration of FIG. 7A, for instance, Ports 1A and 2A can be coupled to ground terminal 620 and/or ground terminal 622, thus grounding the first upper electrodes 602a and the first lower electrodes 604a, while Ports 1B and 2B can be coupled to an input (e.g., positive) signal. In this configuration, Port 3A also can be coupled to the input signal while Port 3B also can be coupled to the ground terminal 620 or 622. In some implementations, the middle layer electrodes 606a and 606b can be patterned so as to have respective widths that are substantially wider than the corresponding widths of the upper layer electrodes 602a and 602b and lower layer electrodes 604a and 604b. In some other implementations, the middle layer electrodes 606a and 606b can be patterned so as to have respective widths that are substantially narrower than the corresponding widths of the upper layer electrodes 602a and 602b and lower layer electrodes 604a and 604b.

In the example of FIG. 7A, the electrodes in the respective conductive layers have longitudinal axes substantially oriented along a Y axis, illustrated in FIG. 6. The X, Y and Z axes of FIG. 6 and additional figures described below are provided for reference and illustrative purposes only. In this example, the electrodes are generally straight along their longitudinal axes, although the electrodes can be curved, i.e., have arced contours, be angled, or have other geometries, depending on the desired implementation. Elongated electrodes having any of these various shapes are sometimes referred to herein as “fingers.” In some implementations a resonator may be formed of only the three top, three middle, and three bottom electrodes shown in FIG. 7A. In some other implementations, additional sets of top, middle, and bottom electrodes also may be included at the same alternating periodic half-wavelength intervals along the width of the resonator. That is, for example, and with reference to the upper conductive layer, such that there are two or more first electrodes 602a and two or more second electrodes 602b. In such an implementation, each first electrode 602a may be separated from each adjacent first electrode 602a by a length substantially equal to λ and with a second electrode 602b bisecting the distance between the two adjacent first electrodes 602a. In various implementations, the total number of electrodes in each of the top, middle, and bottom conductive layers may range from 3 to over 100. In some implementations one or more of the electrodes 602a and 602b, 604a and 604b, and 608a and 608b may be omitted. In some implementations, some of the fingers may have center-to-center spacings slightly different than λ/2. For example, the fingers can be arranged such that they periodically alternate according to a center-to-center spacing of λ/4.

In FIG. 7A, moving from left to right along the width of the CMR (i.e., along the X-axis), the electrodes patterned in each of the upper, middle, and lower electrode layers alternate in polarity along their respective layers. The electrodes create vertical fields (represented approximately by the arrows in FIG. 8A) between the upper and middle electrode layers and between the middle and lower electrode layers, as shown in FIG. 8A. The electrodes also create, at half-wavelength intervals, lateral fields that are approximately dipole in shape. In the case of the middle electrodes shown, the field, represented approximately by the arrows in FIG. 8B, is symmetric about the thickness of the set of lower and upper piezoelectric layers 608 and 610. The total electric field in the CMR 600 is the sum of these vertical and lateral fields shown in FIGS. 8A and 8B. The lateral extent (width) of the first and second middle electrodes 606a and 606b adjusts the relative components of the vertical and lateral electric fields and can be adjusted to optimize coupling. For example, in FIG. 8B, the lateral width of each of the middle electrodes 606a and 606b is greater than that of the upper and lower electrodes, and thus the middle electrodes generate most of the lateral electric field. In this way, the resonator transduces vibration through displacement associated with both the d₃₁ and the d₃₃ piezoelectric coefficients, resulting in a higher kₜ² than can be achieved in traditional topologies that only drive and sense vibration through displacement associated with the d₃₁ coefficient. FIG. 7B shows the approximate corresponding particle displacements for the topology of FIG. 7A (not to scale).

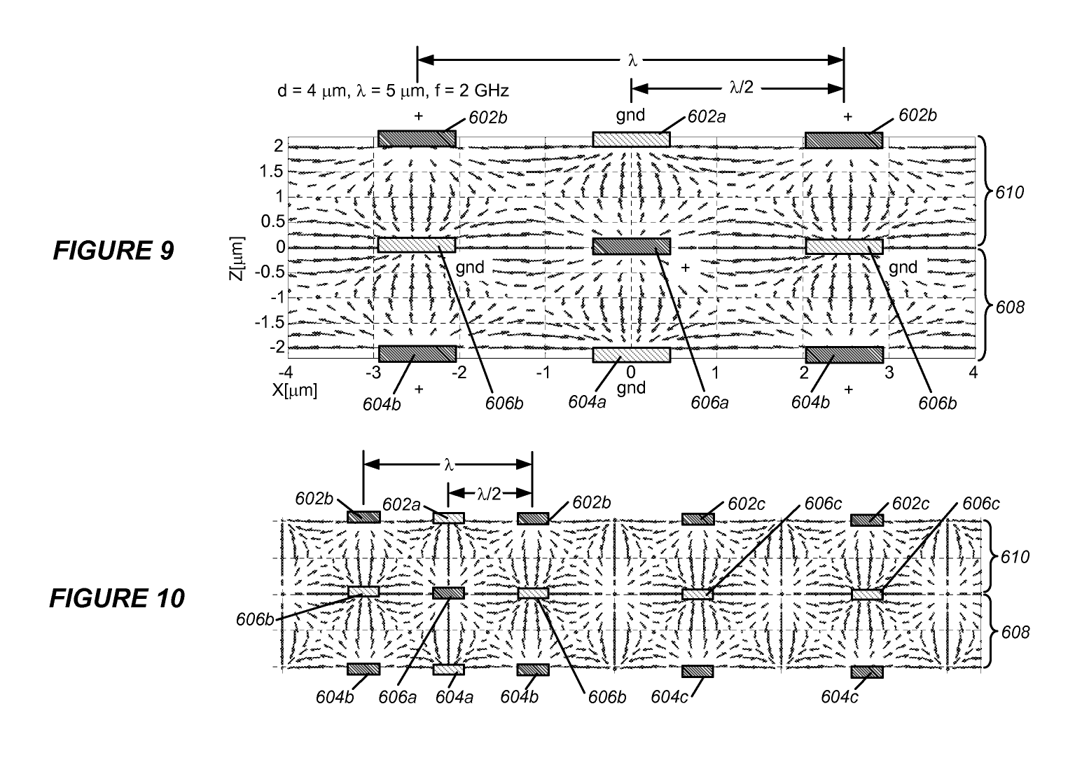

FIG. 9 shows a cross-sectional side view of an example CMR having a topology similar to that of the CMR of FIG. 7A along with corresponding example approximate particle displacements. In FIG. 9, the topology is similar to that of the CMR of FIGS. 7A, 7B, 8A and 8B, but with relatively thick piezoelectric layers 608 and 610 (such as d=4 μm, λ=5 μm, and d/λ=0.8). As shown, the CMR exhibits roughly equal transverse and longitudinal components of displacement, and a higher order deflection across the thickness of the piezoelectric layers. Again, the electrodes 602a, 602b, 604a, 604b, 606a and 606b are positioned to transduce through both the d₃₁ and d₃₃ piezoelectric coefficients. Slightly more than one wavelength is shown and the vertical and horizontal plate dimensions are approximately to scale. That is, in FIG. 9, the center-to-center distance between adjacent electrodes of the same type (such as type 602a or type 602b) is one wavelength while the center-to-center distance between an electrode 602a and an adjacent electrode 602b is a half wavelength.

FIG. 10 shows a cross-sectional side view of another example CMR that includes additional sensing output ports, along with corresponding example approximate particle displacements. In FIG. 10, there are two piezoelectric layers and three patterned electrode layers along with corresponding particle displacements. The example configuration of FIG. 10 is an adaptation of the CMR of FIG. 9 that utilizes the combined d₃₁ and d₃₃ drive scheme of FIG. 9, but which further includes additional electrodes 602c, 604c, and 606c that sense through the displacement associated with only the d₃₃ piezoelectric coefficient. More particularly, the CMR of FIG. 10 is a two-port higher-order S₀ Lamb wave CMR where the input port electrodes 602b, 604b, and 606a receive an input (e.g., positive) signal (such as via Ports 1B, 2B and 3A not shown) and drive displacement through the d₃₁ and d₃₃ piezoelectric coefficients (electrodes 602a, 604a and 606b are coupled to ground via Ports 1A, 2A and 3B not shown). In FIG. 10, the output or sense port electrodes 602c and 604c sense substantially vertically-oriented d₃₃ strain fields (electrodes 606c are coupled to ground), resulting in a resonator with a higher kt².

Features of the proposed solutions include patterning all three electrode layers to efficiently drive the natural mode of vibration of the piezoelectric resonator structure at GHz frequencies. Another feature is the use of single-ended (signal, ground, and floating) or differential (+signal, −signal, ground, floating) electrical routing across all layers of the multilayer piezoelectric resonator. Furthermore, the two-port implementations can reduce feed-through capacitance and improve rejection.

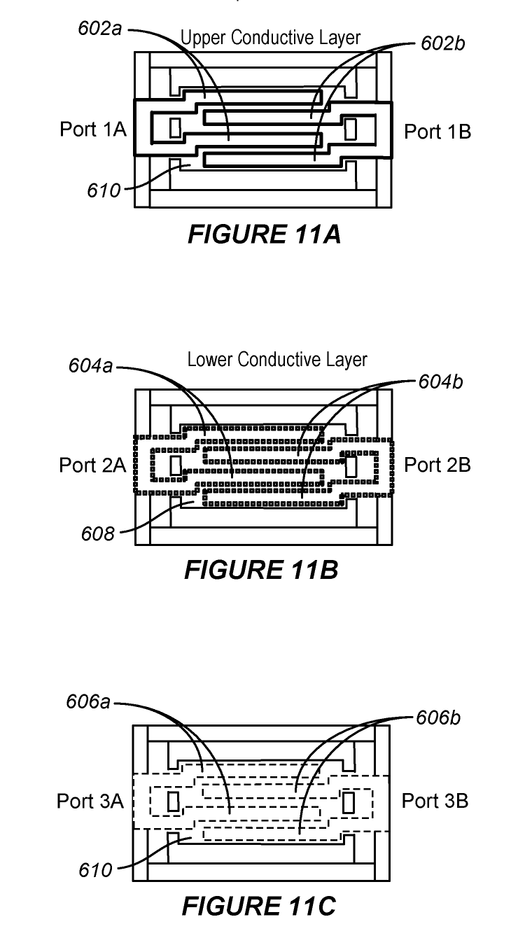

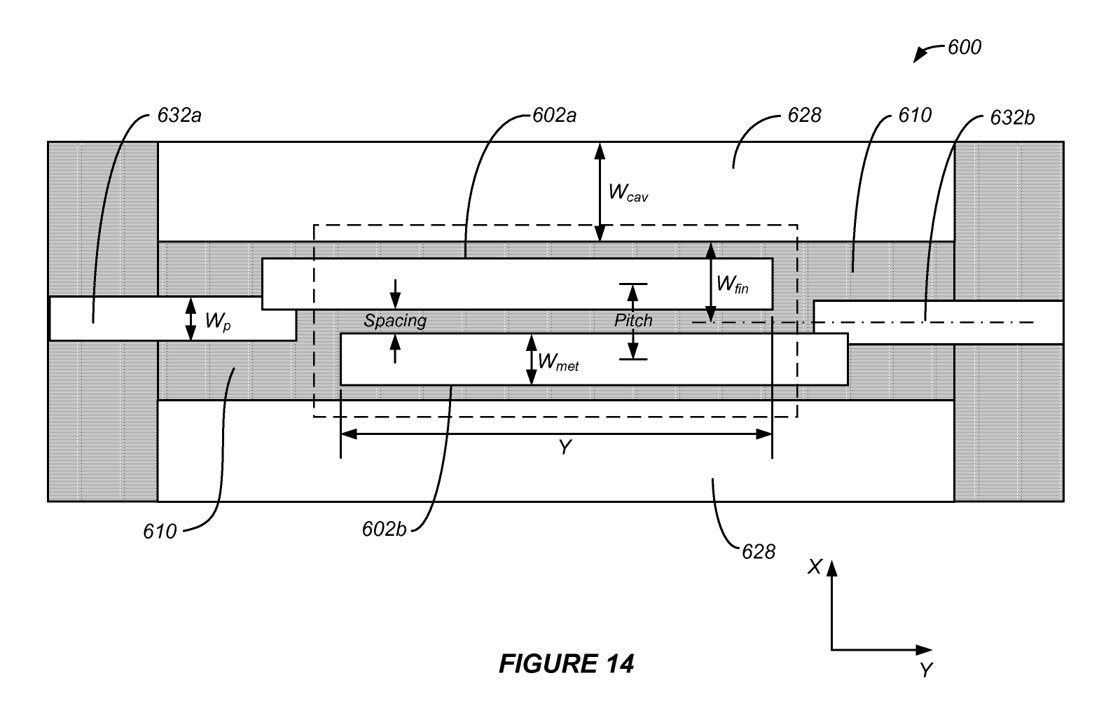

More detailed descriptions of example implementations of the proposed solutions and processes for the fabrication of such will now be described. FIG. 11A shows a top view of an example CMR device. FIG. 11B shows a bottom view of the CMR device of FIG. 11A as viewed from above the resonator. FIG. 11C shows a hidden view of a middle layer in the CMR device of FIG. 11A as viewed from above the resonator. In FIG. 11A, two first electrodes 602a are interdigitated with two second electrodes 602b in the upper conductive layer, similar to the arrangement of FIG. 6. Unlike in FIG. 6, in FIGS. 11A-11C, each of the first electrodes 602a is connected to Port 1A by a respective connecting member, as further explained below with reference to FIG. 14. Separate connecting members are similarly incorporated to establish connections between respective second electrodes 602b and Port 1B. As shown in the bottom view of the CMR device in FIG. 11B, the lower conductive layer includes a corresponding arrangement of first electrodes 604a interdigitated with second electrodes 604b. Similarly, as shown in the hidden view of the CMR device in FIG. 11C, the middle conductive layer includes a corresponding arrangement of first electrodes 606a interdigitated with second electrodes 606b. In some examples, some or all of the first electrodes 602a, 604a, and 606a of the respective conductive layers are aligned with one another, that is, along the Z axis of FIG. 6, while separated by piezoelectric layers 608 and 610. Similarly, in such implementations, some or all of the second electrodes 602b, 604b, and 606b of the respective conductive layers are aligned with one another, that is, along the Z axis of FIG. 6, while separated by piezoelectric layers 608 and 610.

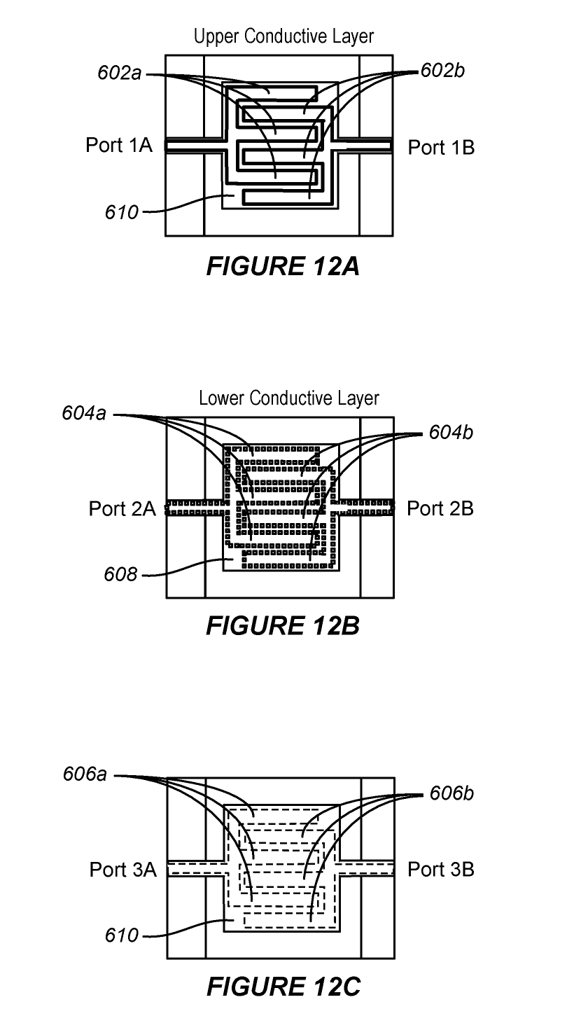

FIG. 12A shows a top view of another example CMR device. FIG. 12B shows a bottom view of the CMR device of FIG. 12A. FIG. 12C shows a hidden view of the middle electrode layer in the CMR device of FIG. 12A. FIGS. 12A-12C show that there can be additional first and second electrodes in each of the respective conductive layers, and the electrodes can have different lengths, widths, and spacings from those in FIGS. 11A-11C. In some examples, some or all of the first electrodes 602a, 604a and 606a of the respective conductive layers are aligned with one another, that is, along the Z axis of FIG. 6, while separated by piezoelectric layers 608 and 610. And again, similarly, some or all of the second electrodes 602b, 604b and 606b of the respective conductive layers are aligned with one another, that is, along the Z axis of FIG. 6, while separated by piezoelectric layers 608 and 610.

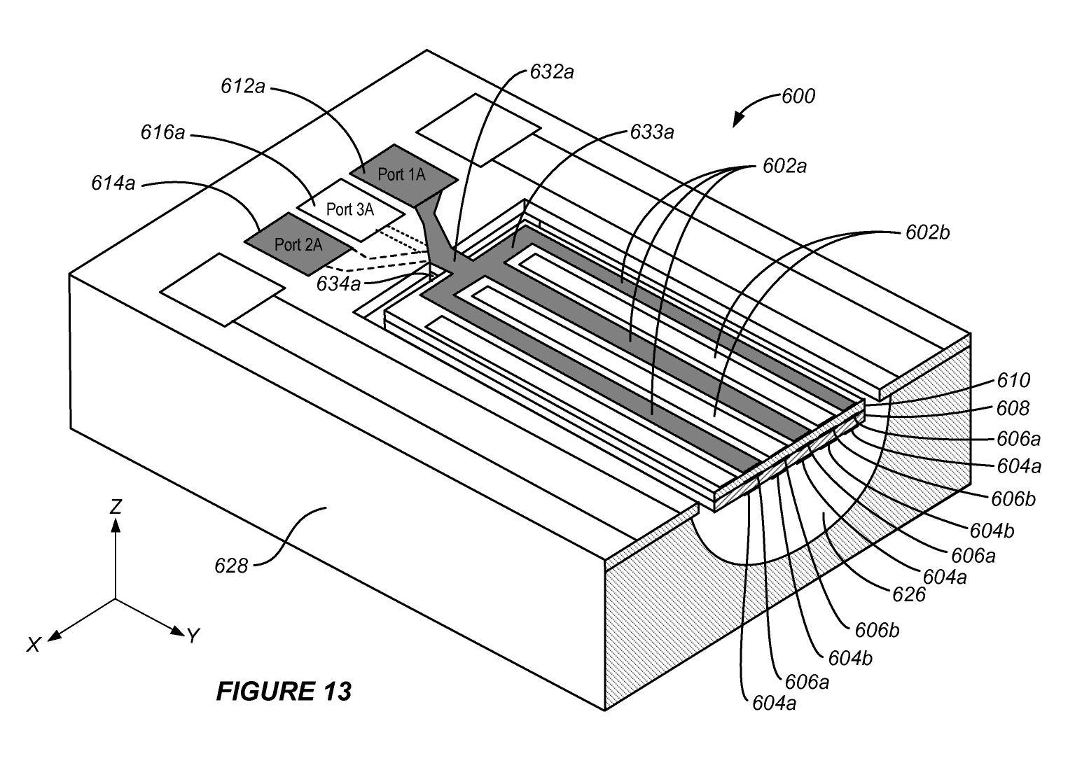

In the examples of FIGS. 11A-11C and 12A-12C, the electrodes in the respective conductive layers are situated in a periodic arrangement and spaced apart from one another, for example, along the X axis of FIG. 6. Each set of electrodes 602a, set of electrodes 602b, set of electrodes 604a, set of electrodes 604b, set of electrodes 606a and set of electrodes 606b is connected to a respective port (e.g., Ports 1A, 1B, 2A, 2B, 3A and 3B, respectively) by a shared connecting member including tethers, as further explained below with reference to FIG. 13.

FIG. 13 shows a perspective cross-sectional view of an example CMR device, such as that shown in FIG. 6. In FIG. 13, resonator structure 600 includes an upper conductive layer of electrodes 602a and 602b, an upper piezoelectric layer 610, a middle layer of electrodes 606a and 606b, a lower piezoelectric layer 608, and a lower conductive layer of electrodes 604a and 604b, as described above. The resonator structure 600 is suspended in a cavity 626 by virtue of a first tether respectively, as well as a matching second tether (not shown) connected at the opposite end of the CMR. In some implementations, each tether is an integrally formed continuance of the lower and upper piezoelectric layers 608 and 610, and the lower, middle, and upper conductive layers 602, 606, and 604. The electrodes can be electrically coupled to the respective ports via conductive pathways, for example, including upper and lower tether interconnects 632a and 634a. In FIG. 13, the tethers serve as physical anchors to hold the resonator structure in the cavity 626. The resonator structure is capable of vibration by virtue of the piezoelectric material layers 608 and 610. The tether interconnect 632a is electrically coupled between the first electrodes 602a of the upper conductive layer and port 612a, while the tether interconnect 634a is electrically coupled between the underlying first electrodes 604a of the lower conductive layer and another port, such as port 614a of FIGS. 6 and 13. The matching pair of tether interconnects on the opposite end of the structure can similarly electrically couple second electrodes 602b and 604b of the upper and lower layers to their respective ports 612b and 614b as described in the example of FIG. 6 above. There also can be a third tether interconnect 636a that is electrically coupled between the first electrodes 606a of the middle conductive layer and port 616a, as well as a matching tether interconnect on the opposite side coupling second electrodes 606b and port 616b. The tether interconnects can be fabricated as extensions of their respective conductive layers and can be on the order of several microns wide, such as along the X axis. In some implementations, the tether interconnects 632a, 632b, 634a, 634b, 636a and 636b are designed such that their respective lengths, such as along the Y axis of FIG. 6, are each an integer number of resonant quarter wavelengths.

In the examples shown in FIGS. 12A-12C and FIG. 13, each set of electrodes has an electrode interconnect electrically coupled to a respective tether interconnect. For instance, in FIG. 13, electrode interconnect 633a is coupled between the first electrodes 602a and the tether interconnect 632a. Thus, in some implementations, the tether interconnect 632a, the electrically coupled electrode interconnect 633a, and the first electrodes 602a form an integral part of the upper conductive layer. Another distinct part of the upper conductive layer includes a corresponding tether interconnect and electrode interconnect integrally coupled to the second electrodes 602b. Likewise, in some implementations, the tether interconnect 634a, an electrically coupled electrode interconnect, and the first electrodes 604a form an integral part of the lower conductive layer while another distinct part of the lower conductive layer includes a corresponding tether interconnect and electrode interconnect integrally coupled to the second electrodes 604b. Again, similarly, a third tether interconnect, an electrically coupled electrode interconnect, and the first electrodes 606a form an integral part of the middle conductive layer while another distinct part of the middle conductive layer includes a corresponding tether interconnect and electrode interconnect integrally coupled to the second electrodes 606b. The resonator structure is partially surrounded by an opening in the form of the cavity 626 and is coupled to a supporting structure including a substrate 628, which supports the resonator structure, by virtue of the tethers.

The resonator structures of FIGS. 6-13 include patterns of metal electrodes in the upper, middle, and lower conductive layers that, when provided one or more electrical input signals, cause the piezoelectric layers to have a motional response. The motional response can include a vibrational oscillation along one or more of the X, Y and Z axes. The resonant frequency response of the CMR structure can be controlled according to a periodic arrangement of the electrodes in the conductive layers, for instance, by adjusting the width(s) as well as the spacing(s) of the electrodes from one another in a conductive layer, such as along the X axis of FIG. 6, as further explained below.

In FIGS. 6-13, the pattern of interdigitated first electrodes and second electrodes of the respective conductive layers are periodic in one direction, for instance, along the X axis of FIG. 6. As illustrated, the periodic arrangement of electrodes 602a and 602b includes alternating areas of metal, representing electrode regions, and space regions, i.e., areas without metal. Such space regions between the electrodes are also referred to herein as “spaces.” In various implementations, the areas of metal and the spaces have the same width, the areas of metal are wider than the spaces, the areas of metal are narrower than the spaces, or any other appropriate relation between the metal widths and spaces. The finger width of the CMR, a parameter based on a combination of electrode width and spacing, as described in greater detail below with reference to FIG. 14, can be adjusted to control one or more resonant frequencies of the structure. For instance, a first finger width in a conductive layer can correspond to a first resonant frequency of the CMR, and a second finger width in the conductive layer can provide a different second resonant frequency of the CMR.

The CMR structure can be driven into resonance by applying a harmonic electric potential, for example, to Ports 1B, 2B and 3A (or alternatively to Ports 1A, 2A and 3B when Ports 1B, 2B and 3A are grounded) that varies in time across the patterned conductive layers. The layout and interconnectivity of the periodic electrodes transduce the desired mode of vibration while suppressing the response of undesired spurious modes of vibration of the structure. For example, a specific higher order vibrational mode can be transduced without substantially transducing other modes. Compared to its response to a constant DC electric potential, the amplitude of the mechanical response of the resonator is multiplied by the Q factor (the typical Q factor is on the order of 500 to 5000). Engineering the total width of the resonator structure, the number of electrode periods, and or the thickness of the piezoelectric layers provides control over the impedance of the resonator structure by scaling the amount of charge generated by the motion of the piezoelectric material.

FIG. 14 shows a top view of an example resonator device. In the implementation of FIG. 14, a resonator structure 600 is configured as a CMR, with the electrodes in the respective conductive layers having longitudinal axes substantially parallel to one another and extending along the Y axis, as illustrated. A resonator structure generally has a finger width, W_{fin}, representing the width of each sub-resonator, which primarily includes one electrode and half of the width of the exposed piezoelectric material on either side of the one electrode along the X axis, for example, as shown in FIG. 14. The electrode width, that is, the width of an individual electrode, Wₘₑₜ, is sometimes smaller than the finger width, to limit the feed-through capacitance between electrodes. The pitch of the resonator structure generally refers to the distance between mid-points of electrodes along the X axis, as shown in FIG. 14. The spacing of electrodes refers to the gap between the edges of adjacent electrodes along the X axis. The resonant frequency of the resonator structures disclosed herein is primarily determined by the finger width or pitch. The electrode width and spacing have second-order effects on the frequency. The finger width and pitch are correlated with the electrode width and spacing parameters, by definition. Pitch is often equal to finger width, as shown in the example of FIG. 14.

In FIG. 14, in one example, the upper electrodes 602a and 602b have an electrode width along the X axis, Wₘₑₜ, of 4.8 μm. Connecting members 632a and 632b, which can include tether interconnects in some examples, are coupled to the respective electrodes 602a and 602b. The connecting members 632a and 632b have a connecting member width, Wₚ, which can be smaller than Wₘₑₜ in an example. In other instances, Wₚ is the same size or larger than Wₘₑₜ, depending on the desired configuration. The finger width of the electrodes, W_{fin}, which corresponds to the half-width of the piezoelectric layer 610 in this example, is 6.4 um. W_{cav}, the cavity width of cavity 626 along the X axis can be an integer multiple of W_{fin}, such as 2*W_{fin} (e.g., 12.8 um) or other measurement. Thus, in this instance, W_{cav} is approximately the same as the full piezoelectric layer width. In this example, a distance Y, in which the upper electrodes 602a and 602b are adjacent to one another, can be on the order of 128 um or 256 um, by way of example. Of course, other dimensions or values for Y can be used in other implementations and other applications.

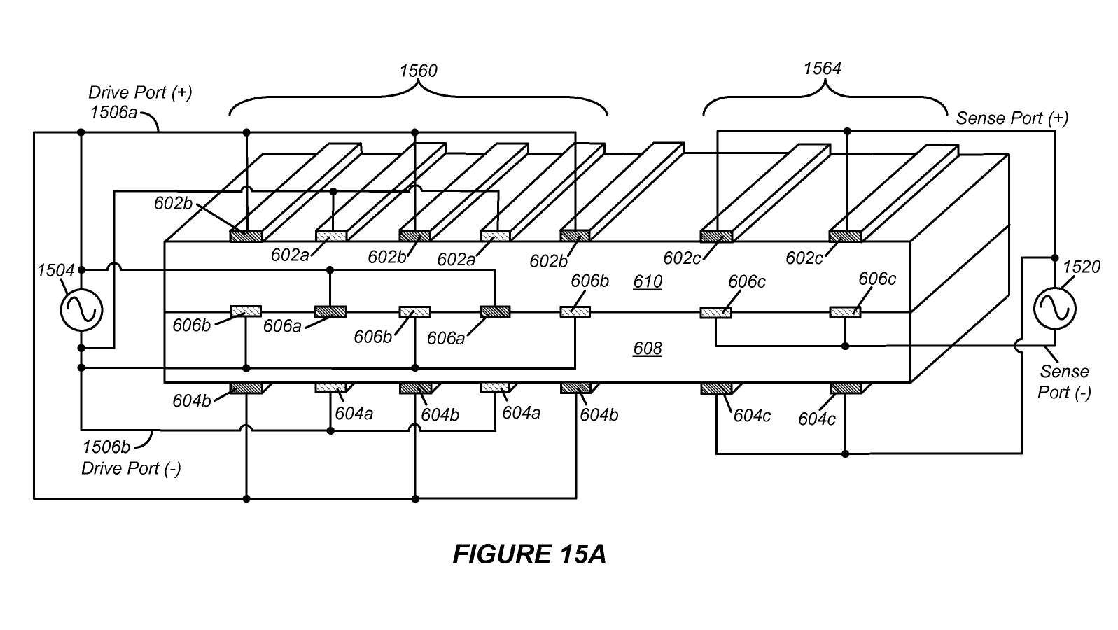

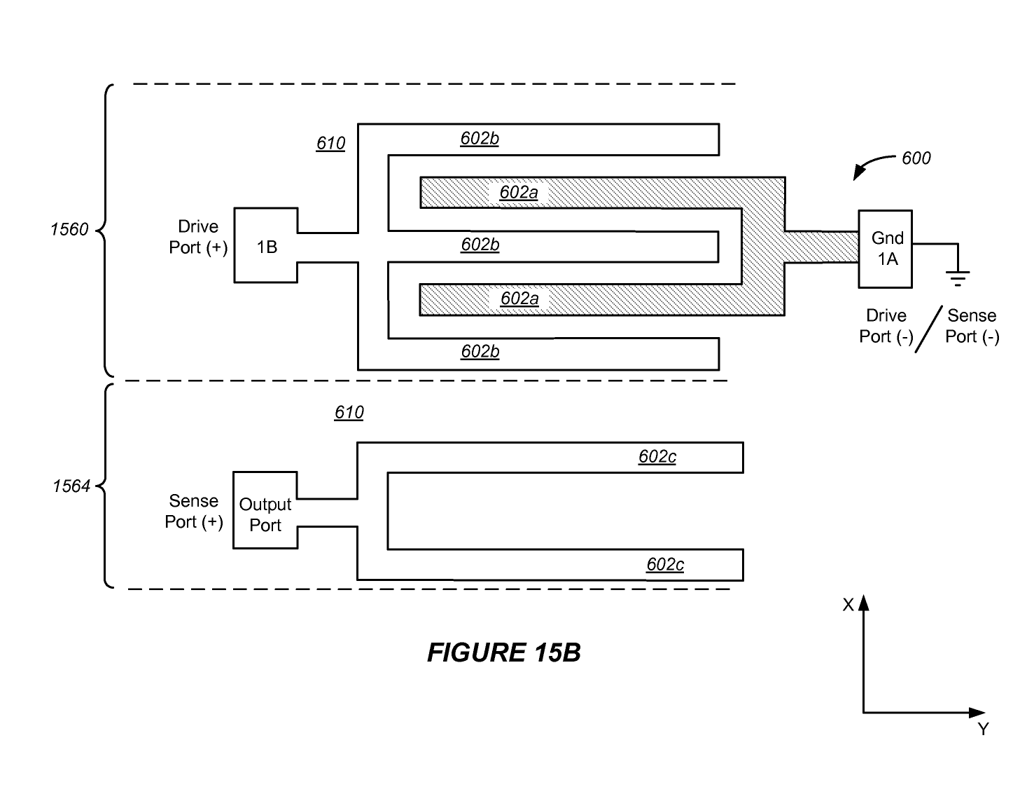

FIG. 15A shows a perspective cross-sectional view of an example two-port resonator structure, such as, for example, an implementation of the two-port resonator structure of FIG. 10. In particular, the resonator structure of FIG. 15A includes a set of input (driving) ports and a set of output (sensing) ports. The resonator structure 600 includes an upper conductive layer of electrodes 602a and 602b, an upper piezoelectric layer 610, a middle conductive layer of electrodes 606a and 606b, a lower piezoelectric layer 608, and a lower conductive layer of electrodes 604a and 604b, with the layers stacked as described above. In FIG. 15A, there is an input port, for example Port 1B, at which an input electrical signal can be delivered to each of second electrodes 602b of the upper conductive layer. In the illustrated implementation, the input electrical signal applied to Port 1B also is delivered, via Ports 2B and 3A, to each of second electrodes 604b and first electrodes 606a of the lower and middle conductive layers, respectively. For simplicity, Ports 1B, 2B, and 3A will be collectively referred to hereinafter as DrivePort(+). Similarly, for simplicity, Ports 1A, 2A, and 3B will be collectively referred to hereinafter as DrivePort(−).

DrivePort(+) can be coupled to receive the input electrical signal from various components, such as an amplifier or an antenna. In the illustrated implementation, an alternating current (AC) voltage source 1504 simulates the electrical signal delivered by such a component. The AC voltage source 1504 has a first terminal 1506a coupled to DrivePort(+) and a second terminal 1506b coupled to DrivePort(−), which is coupled to ground in this example. In this way, an input AC signal can be provided from voltage source 1504 to DrivePort(+) and, hence, to second electrodes 602b, second electrodes 604b, and first electrodes 606a, of the upper, lower, and middle layers of the resonator, respectively. An electric field caused by the alternating voltage of the AC signal is applied in the piezoelectric layers 608 and 610, as well as across the width of the piezoelectric layers 608 and 610, as described above with reference to FIGS. 8A and 8B respectively.

As referenced above, the thickness of the structure 600 is generally measured along the Z axis, and the length is measured along the Y axis, in the example of FIG. 15A. The total width, referring to the width of the overall structure 500, as well as finger width, spacing, and electrode width are measured along the X axis, in the example of FIG. 15A. The electric field is applied in a manner to transduce mechanical resonance such that piezoelectric layers 608 and 610 experience displacement back and forth along the X, Y and Z axes. This includes both lateral displacement, that is, back and forth along the width and length of the structure (such as substantially along the respective X and Y axes of FIG. 15A), as well as transverse displacement back and forth along the thickness of the structure (such as substantially along the Z axis of FIG. 15A).

As described above, FIG. 15A, like FIG. 10, illustrates a two-port structure. In some implementations, the third electrodes 602c and 604c are coupled to SensePort(+), which represents a first output port in this configuration. In some implementations, third electrodes 606c are coupled to SensePort(−), which is coupled to ground in the illustrated implementation.

FIG. 15B shows a top view of the example two-port resonator structure of FIG. 15A. In FIGS. 15A and 15B, the input electrodes 602b, 606a, and 604b of the respective upper, middle, and lower conductive layers are situated in a first region 1560 of the structure 600 along the X axis. In this example, the output electrodes 602c and 604c of the respective upper and lower conductive layers are situated in a second region 1564 along the X axis.

In FIGS. 15A and 15B, moving from left to right across the width, the resonator structure 600 includes a first-type vertically-stacked arrangement of fingers: the upper and lower input electrodes 602b and 604b and middle grounded electrode 606b, and a second-type vertically-stacked arrangement of fingers: the upper and lower grounded electrodes 602a and 604a and middle input electrode 606a. In some implementations, there can be a plurality of the first-type arrangements and a plurality of the second-type arrangements that periodically alternate along a width of region 1560. For example, FIGS. 15A and 15B illustrate a CMR with three first-type arrangements of fingers and two second-type arrangements of fingers, where each second-type arrangement is neighbored on each side by a first-type arrangement. In FIGS. 15A and 15B, the resonator structure 600 additionally includes a third-type vertically-stacked arrangement of fingers: the upper and lower sensing output electrodes 602c and 604c and the middle ground electrode 606c. Again, in some implementations, there can be a plurality of the third-type arrangements along the width of region 1564 (there are two third-type arrangements in FIGS. 15A and 15B). In some other implementations, the lower, middle, and upper electrodes in the region 1564 can be arranged as, or similar to the way, they are arranged in region 1560.

In FIGS. 15A and 15B, the first, second, and third arrangements of fingers defining the respective sub-resonators are mechanically and acoustically coupled by virtue of the shared piezoelectric layers 608 and 610. That is, the two sub-resonators in respective regions 1560 and 1564 are within a single mechanical body. In some implementations, the two sub-resonators also can be viewed as separate resonators, each having a portion of each of the piezoelectric layers 608 and 610. Since the two sub-resonators are in contact with one another in shared piezoelectric layers 608 and 610, the two sub-resonators mechanically interact with one another. For example, the two sub-resonators can experience mechanical movement and physical displacement in the form of the sub-resonators vibrating in phase or out of phase with each other.

In some implementations, there are two resonant modes of the structure 600, that is, in the form of the two resonant frequencies. This is due to the incorporation of the two sub-resonators in regions 1560 and 1564, respectively, of the single structure 600. At resonance, an AC input signal delivered to Port 1B and having a frequency coinciding with the natural resonant frequency of the structure 600 causes the structure 600 to vibrate. In one example of this second order system, in a first mode, the sub-resonators vibrate in phase with one another, essentially moving in the manner of a single resonator. In a second mode, the two sub-resonators vibrate out of phase with one another.

A filter bandwidth of the structure 600 can be defined by the difference between the higher resonant frequency and the lower resonant frequency of the structure 600. The finger width, W_{fin}, in the structure 600 can be engineered to control, set, and adjust the resonant frequencies, and thus set the filter bandwidth. In some examples, W_{fin} directly determines the lower resonant frequency. In some examples, the higher resonant frequency is indirectly determined by W_{fin} and also affected by the manner in which an acoustic wave travels in structure 600 back and forth along the X axis. A center frequency between the higher and lower resonant frequencies also can be determined by W_{fin}. The total width, Wₜ, of the structure also can be engineered to control, set, and adjust the filter bandwidth defined by the difference between the higher and lower resonant frequencies. The finger width, W_{fin}, can be defined by layout and photolithography in fabrication of the structure. In some applications, the resonant frequencies can provide multiple frequency operation, e.g., from 10 MHz up to microwave frequencies on a single chip.

The piezoelectric layers 608 and 610 of the disclosed resonators can vibrate and move in all directions at resonant frequencies, for instance, in planes oriented along the X and Y axes, X and Z axes, and Y and Z axes. In one example of a CMR, electrical fields with varying horizontal and vertical components are induced in piezoelectric layers 608 and 610 along the X and Z axes, causing, through the d₃₁ and d₃₃ piezoelectric coefficients, mechanical stress and resulting strain in the piezoelectric layer with components along the width and thickness of the structure. This mechanical energy causes an electric potential to be generated across third electrodes 602c and 606c and an electric potential to be generated across third electrodes 606c and 604c. This transduced potential is sensed as an output electrical signal at SensePort(+) and can be measured by one or more sensors 1520 coupled between SensePort(+) and SensePort(−).

The fundamental frequency for the displacement of the piezoelectric layer can be set in part lithographically by the planar dimensions of the upper electrodes, the middle electrodes, the lower electrodes, and/or the piezoelectric layers. At the device resonant frequency, the electrical signal across the device is reinforced and the device behaves as an electronic resonant circuit. For instance, the resonator structures described above can be implemented by patterning the input electrodes and output electrodes of a respective conductive layer symmetrically.

In some implementations, the resonant frequency of a CMR can be directly controlled by setting the finger widths. One benefit of such a control parameter is that multi-frequency filters can be fabricated on the same chip. The CMR 600 has a resonant frequency associated with the finger width, which is based on the spacing in combination with the electrode width of electrodes 602a and 602b, that is, along the X axis. The finger width in a conductive layer of the CMR structure can be altered to adjust the resonant frequency. For instance, in some implementations, the resonant frequency is lowered as the finger width increases, and vice versa.

The total width, length, and thickness of the resonator structure are parameters that also can be designated to optimize performance. In some CMR implementations, the finger width of the resonator is the main parameter that is controlled to adjust the resonant frequency of the structure, while the total width multiplied by the total length of the resonator (total area) can be set to control the impedance of the resonator structure. In one example, the lateral dimensions, i.e., the width and length of resonator structure 600 can be on the order of several 100 μm by several 100 μm for a device designed to operate around 1 GHz. In another example, the lateral dimensions are several 1000 μm by several 1000 μm for a device designed to operate at around 10 MHz. A suitable thickness of each of the piezoelectric layers 608 and 610 can be about 0.01 to 10 μm thick.

The pass band frequency can be determined by the layout of the resonator structure, as can the terminal impedance. For instance, by changing the shape, size and number of electrodes, the terminal impedance can be adjusted. In some examples, longer fingers yield smaller impedance. This, in turn, is inversely proportional to the capacitance of the CMR. The resonant frequencies of the CMR structures described herein are generally insensitive to the fabrication process, to the extent that the piezoelectric thickness and thicknesses of the conductive layers do not significantly impact the frequency. The impedance and the frequency can be controlled independently, since the length and the width/spacing of electrodes are in perpendicular directions.

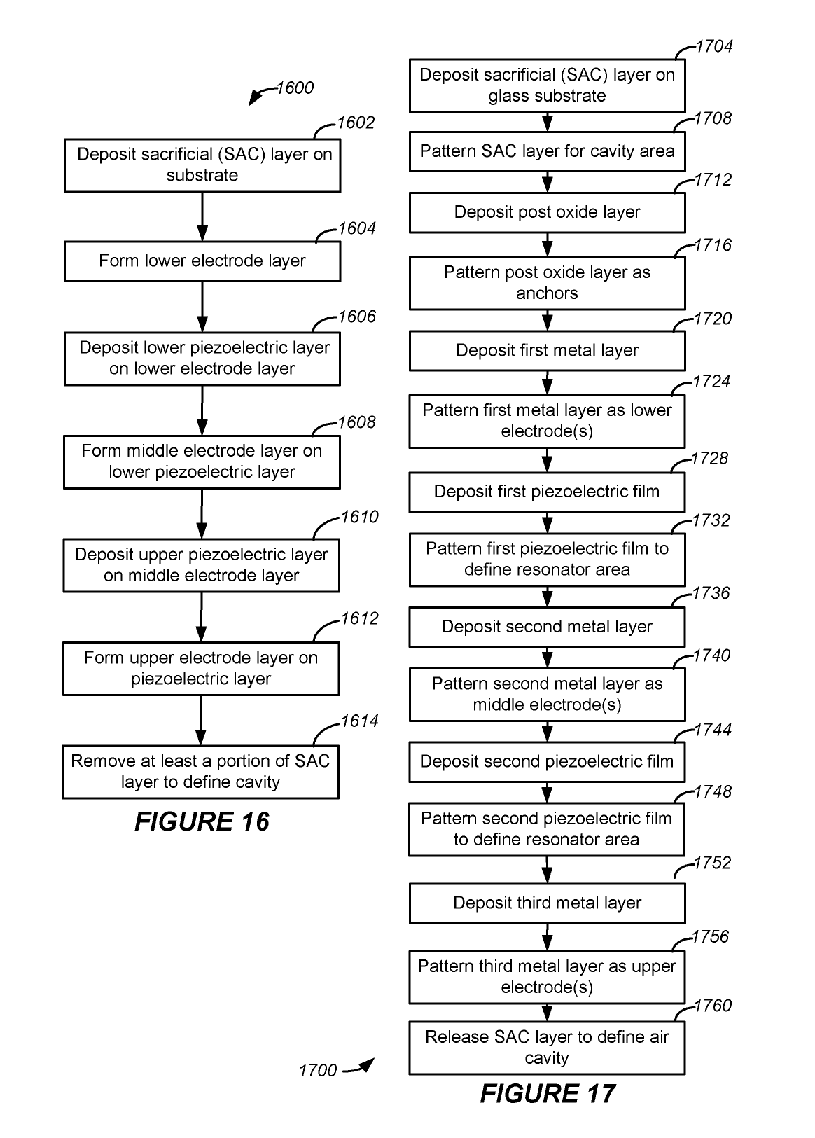

FIG. 16 shows a flow diagram illustrating an example process for forming an example resonator structure. In one example, the resonator structure is the CMR 600 shown in FIG. 6. In FIG. 16, process 1600 begins in block 1602 in which a sacrificial (SAC) layer is deposited on a substrate. The SAC layer can have various shapes and sizes, and can be shaped to cover all or some portion of the substrate, depending on the desired implementation. In block 1604, a lower electrode layer is formed on the SAC layer. The lower electrode layer is made of a conductive material such as metal and can be patterned to define two or more sets of electrodes (e.g., first and second electrodes 604a and 604b), depending on the desired configuration. When more than one electrode is defined, the electrodes can be connected at separate ports of the resonator device. In block 1606, a lower piezoelectric layer (such as piezoelectric layer 608) is deposited on the lower electrode layer. In block 1608, a middle electrode layer is then formed on the lower piezoelectric layer. The middle electrode layer also can be patterned to define more than one electrode or set of electrodes (such as first and second electrodes 606a and 606b). In block 1610, an upper piezoelectric layer (such as piezoelectric layer 610) is then deposited on the middle electrode layer. In block 1612, an upper electrode layer is then formed on the upper piezoelectric layer. The upper electrode layer also can be patterned to define more than one electrode or set of electrodes (such as first and second electrodes 602a and 602b). In some implementations, overlaying groups of electrodes can be defined in the upper, middle, and lower electrode layers on opposite surfaces of the upper and lower piezoelectric layers. In block 1614, part or all of the SAC layer is removed to define a cavity beneath the resonator structure.

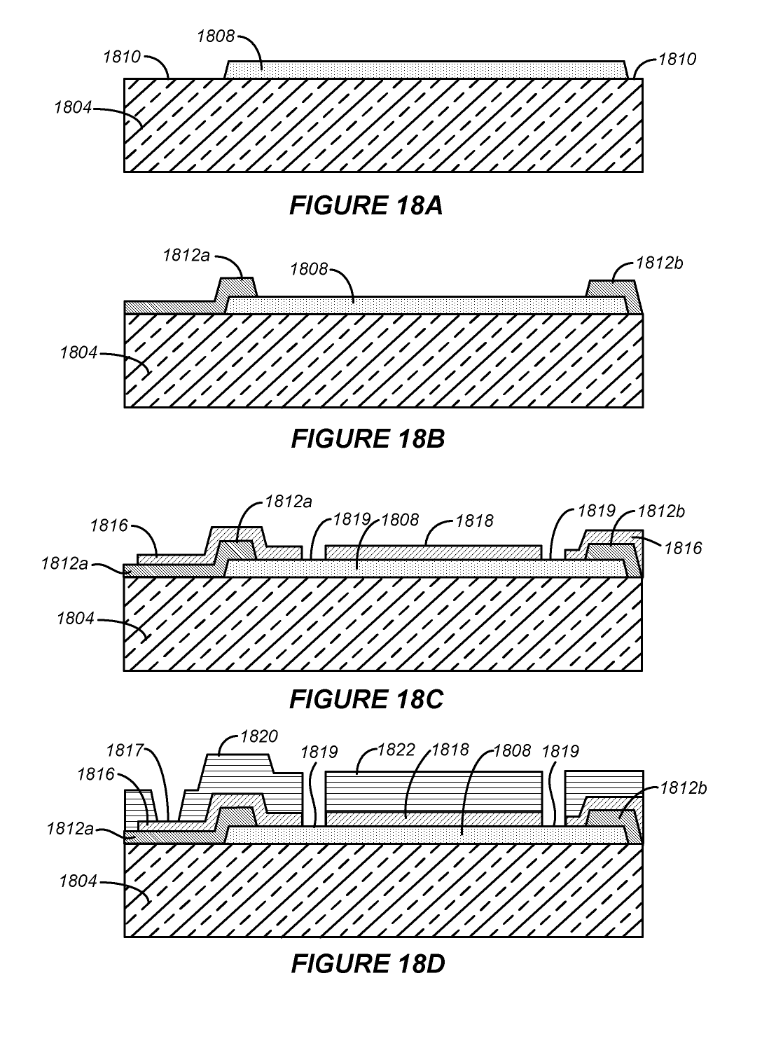

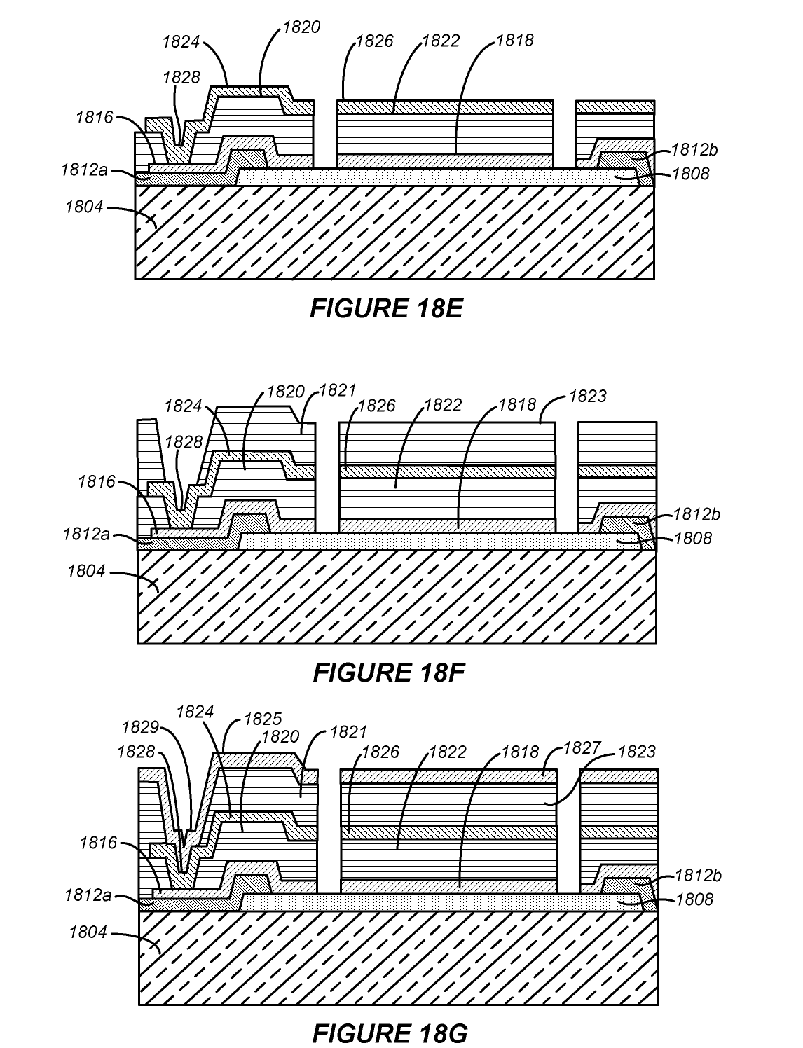

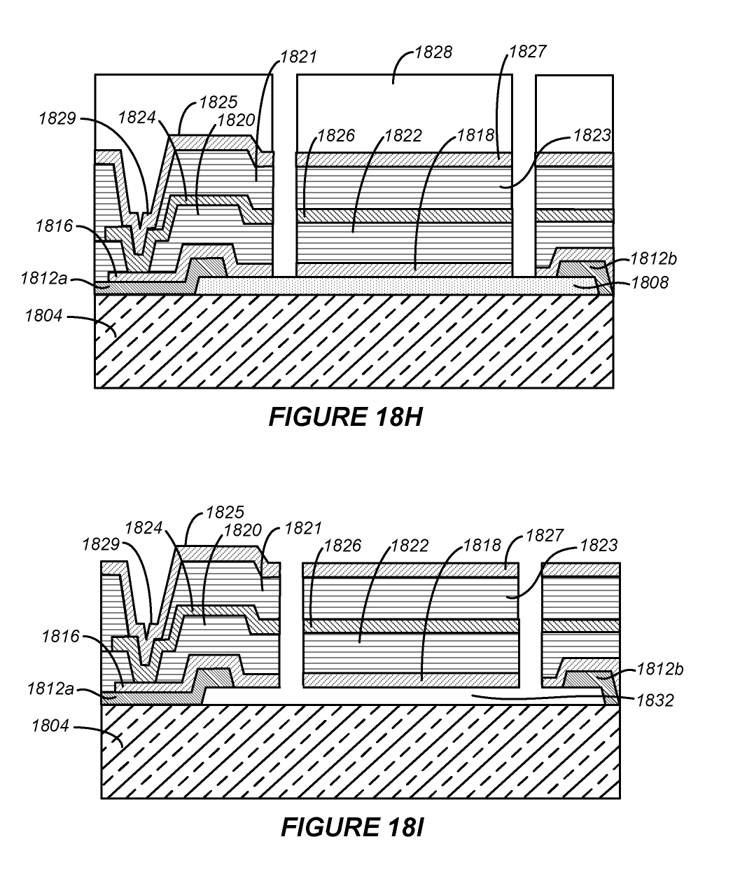

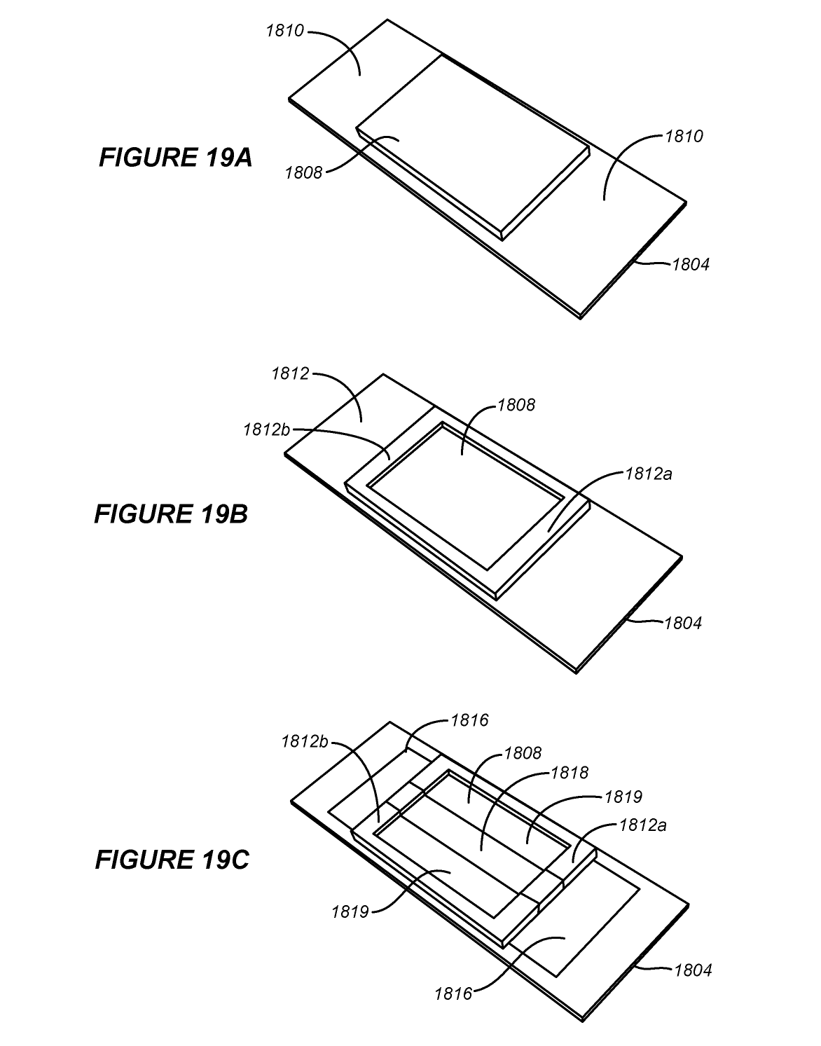

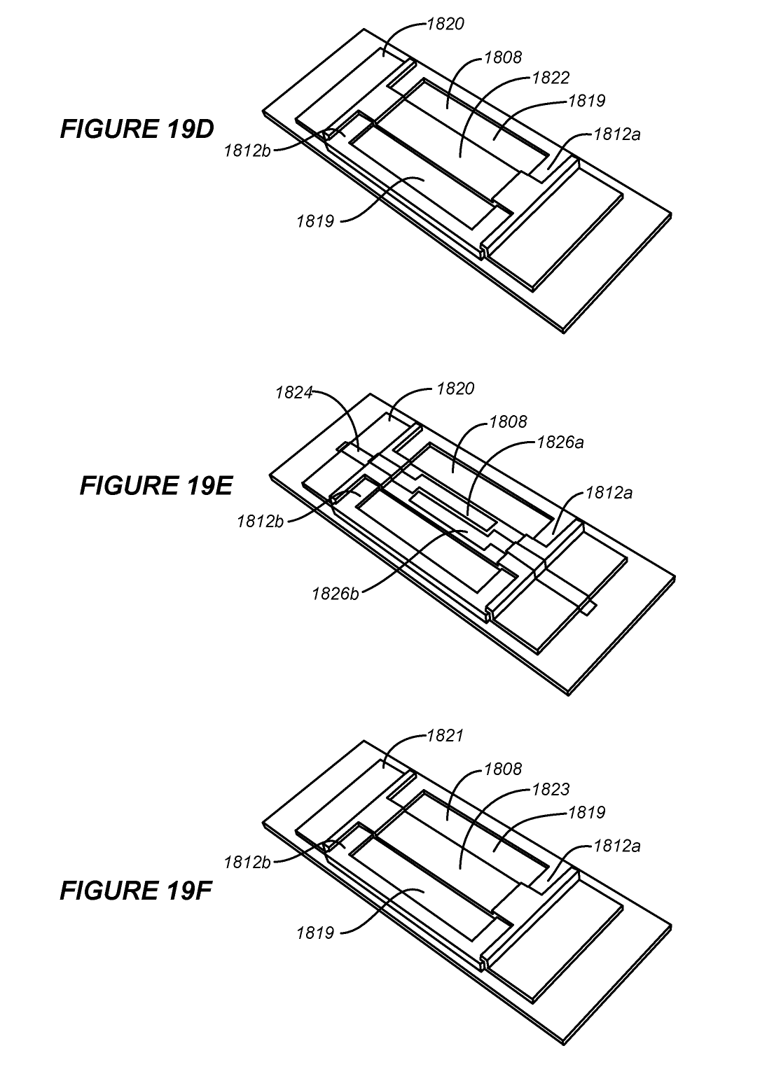

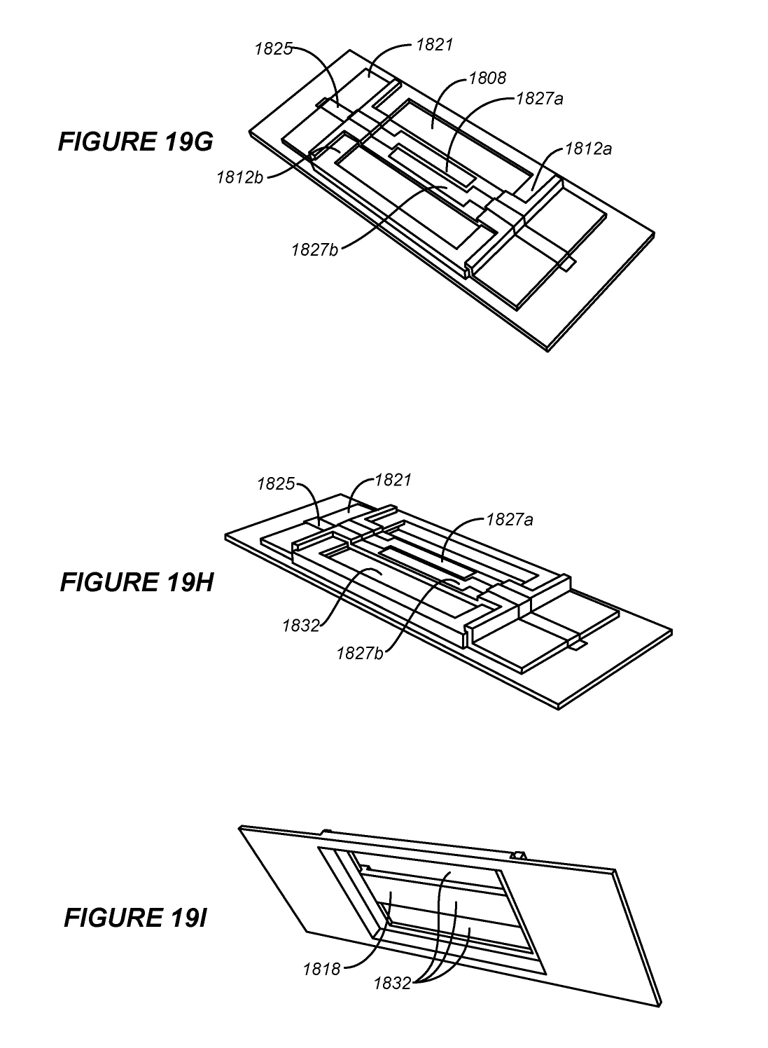

FIG. 17 shows a flow diagram illustrating an example process for forming a staggered resonator structure. FIGS. 18A-18I show cross-sectional schematic illustrations of example stages of staggered resonator fabrication in an example process, for instance, as represented in FIG. 16 or FIG. 17. FIGS. 19A-19I show perspective views of example stages of staggered resonator fabrication in an example process, for instance, as represented in FIG. 16 or FIG. 17.

In FIG. 17, process 1700 begins in block 1704 in which a SAC layer 1808 is deposited on a glass substrate 1804, as shown in FIGS. 18A and 19A. To form the staggered structure of FIGS. 18 and 19, in block 1708, SAC layer 1808 is patterned using an appropriately shaped and aligned mask such that SAC layer 1808 overlays a portion of substrate 1804 and exposes end portions 1810 of the surface of substrate 1804 on respective ends of SAC layer 1808. The SAC layer 1808 defines a region in which a cavity will be formed to substantially isolate the resonator structure from the substrate 1804, as further described below. The SAC layer 1808 can be formed of silicon oxynitride (SiON), silicon oxide (SiOx), molybdenum (Mo), germanium (Ge), amorphous silicon (a-Si), poly-crystalline silicon, and/or various polymers, for example. In some implementations of the process 1700, a suitable thickness of SAC layer 1808 is in the range of about 0.5 μm to 3 μm. In one example, SAC layer 1808 is formed of Mo and has a thickness of about 0.5 μm.

In block 1712, a post oxide layer 1812 is deposited over SAC layer 1808 and exposed surface portions 1810 of glass substrate 1804. In block 1716, to form the staggered structure of FIGS. 18 and 19, the post oxide layer 1812 is patterned using an appropriate mask to expose a top portion of the sacrificial layer 1808, as shown in FIGS. 18B and 19B. The remaining portions 1812a and 1812b of the post oxide layer define anchor structures on sides of the structure, as shown in FIGS. 18B and 19B, covering surface portions 1810 of substrate 1804. The post oxide layer 1812 can be formed of materials such as SiOx and SiON and have a thickness, for example, on the order of about 1 μm to 3 μm. In some other implementations, post oxide layer 1812 can be formed of nickel silicide (NiSi) or molybdenum silicide (MoSi₂). In some examples, post oxide layer 1812 is about 0.5 μm, or can be thicker, in the range of about 3 μm to about 5 μm.

In block 1720, a first metal layer 1816 is deposited such that it overlays the post oxide anchors 1812a and 1812b as well as the exposed region of SAC layer 1808. Metal layer 1816 can be formed of aluminum (Al), Al/titanium nitride (TiN)/Al, aluminum copper (AlCu), Mo, or other appropriate materials, and have a thickness of 750 to 3000 Angstroms depending on the desired implementation. In some cases, the metal layer 1816 is deposited as a bi-layer with a metal such as Mo deposited on top of a seed layer such as AlN. An appropriate thickness for the seed layer can be, for example, 100 to 1000 Angstroms. When Mo is used, the total thickness of the metal layer 1816 can be about 3000 Angstroms. In some implementations or applications, suitable thicknesses range from about 0.1 μm to 0.3 μm. In yet other implementations or applications, suitable thicknesses may range from about 0.01 μm to 10 μm. Other suitable materials for metal layer 1816 include aluminum silicon (AlSi), AlCu, Ti, TiN, Al, platinum (Pt), nickel (Ni), tungsten (W), ruthenium (Ru), and combinations thereof. Thicknesses can range from about 0.1 μm to about 0.3 μm, depending on the desired implementation. As shown in FIGS. 18C and 19C, in block 1724, the first metal layer 1816 is patterned using, for instance, an appropriate mask to define one or more lower electrodes 1818. In some implementations, the one or more lower electrodes can be shaped to match overlaying upper electrodes. In the example of FIGS. 18C and 19C, metal layer 1816 is formed to have a single electrode 1818 in the shape of a strip, which extends laterally across the SAC layer 1808 and exposes the SAC layer 1808 on sides 1819 of the strip, as shown in FIG. 19C. The exposed areas 1819 of the SAC layer 1808 in FIG. 19C are shown as vias in the cross section depicted by FIGS. 18C-18G, for purposes of illustration.

In block 1728, a first lower piezoelectric layer, such as film 1820, is deposited on the structure. In block 1732, the lower piezoelectric film 1820 is patterned using an appropriate mask such that strip 1822 of the piezoelectric film 1820 directly overlays the lower electrode portion 1818, shown in FIGS. 18D and 19D. Again, as with the deposition and formation of the lower electrode layer 1818, side areas 1819 of the SAC layer 1808 remain exposed from above. The lower piezoelectric layer 1820 can be formed of AlN and have a thickness, for example, between about 1 μm and about 2 μm, although other thicknesses can be used depending on the desired implementation. The lower piezoelectric film 1820 is patterned at one end of the structure to have one or more vias 1817, exposing a portion of the first metal layer 1816 for conductive contact to be made to the first metal layer 1816, as shown in FIG. 18D.

In FIG. 17, a second metal layer 1824 is deposited and patterned, in blocks 1736 and 1740, to define middle electrodes 1826, as shown in FIGS. 18E and 19E. The second metal layer 1824 can be formed of Mo, for example, as well as other materials as described above for forming the first metal layer 1816. In one example, the second metal layer 1824 is formed of Mo, and has a thickness of about 2000 Angstroms. In other implementations or applications, suitable thicknesses range from about 0.1 μm to 0.3 μm. In yet other implementations or applications, suitable thicknesses may range from about 0.01 μm to 10 μm. As illustrated in FIG. 19E, when second metal layer 1824 is patterned, in some implementations, at least one pair of adjacent electrodes 1826a and 1826b is formed. In one implementation, the electrodes 1826a and 1826b have longitudinal axes extending along the structure from opposite ends, as shown in FIG. 19E. Thus, the respective electrodes 1826a and 1826b can be connected to different ports, depending on the desired configuration of input and output signals using the resonator structure. In some implementations, a contact region 1828 of the second metal layer 1824 can be deposited in via 1817 so the first and second metal layers are in conductive contact with one another.

In block 1744, a second upper piezoelectric layer, such as film 1821, is deposited on the structure. In block 1748, the upper piezoelectric film 1821 is patterned using an appropriate mask such that strip 1823 of the piezoelectric film 1821 directly overlays the lower electrode portion 1818, the lower strip 1822 of the piezoelectric film 1820, and the middle electrodes 1826, shown in FIGS. 18F and 19F. Again, as with the deposition and formation of the lower electrode layer 1818, side areas 1819 of the SAC layer 1808 remain exposed from above. The upper piezoelectric layer 1821 can be formed of AlN and have a thickness, for example, between about 1 μm and about 2 μm, although other thicknesses can be used depending on the desired implementation. Upper piezoelectric film 1821 is patterned at one end of the structure to have one or more vias 1817, exposing a portion of the first metal layer 1816 and second metal layer 1824 for conductive contact to be made possible to the first metal layer 1816 and second metal layer 1824, as shown in FIG. 18F.

In FIG. 17, a third metal layer 1825 is deposited and patterned, in blocks 1752 and 1756, to define upper electrodes 1827, as shown in FIGS. 18G and 19G. The third metal layer 1825 can be formed of AlCu, for example, as well as other materials as described above for forming the first and second metal layers 1816 and 1824. In one example, the third metal layer 1825 is formed of AlCu, and has a thickness of about 2000 Angstroms. In other implementations or applications, suitable thicknesses range from about 0.1 μm to 0.3 μm. In yet other implementations or applications, suitable thicknesses may range from about 0.01 μm to 10 μm. As illustrated in FIG. 19G, when third metal layer 1825 is patterned, in some implementations, at least one pair of adjacent electrodes 1827a and 1827b is formed. In one implementation, the electrodes 1827a and 1827b have longitudinal axes extending along the structure from opposite ends, as shown in FIG. 19G. Thus, the respective electrodes 1827a and 1827b can be connected to different ports, depending on the desired configuration of input and output signals using the resonator structure. In some implementations, a contact region 1829 of the third metal layer 1825 can be deposited in via 1817 so the third metal layer is in conductive contact with the first and second metal layers.

In some implementations, following the formation of the third metal layer 1825, a release protection layer 1828 such as AlOx can be deposited using atomic layer deposition (ALD), physical vapor deposition (PVD), or other appropriate techniques and patterned to protect sidewalls of the electrodes in the first, second, and third metal layers 1816, 1824, and 1825 and the sandwiched piezoelectric layers 1820 and 1821, as shown in FIG. 18H. In some implementations, the release protection layer 1828 is patterned in block to overlay the third metal layer 1825, as shown in FIG. 18H. The side areas 1819 remain exposed. In some implementations, the release protection layer 1828 can be formed of SiON, and have a thickness of about 1000 to 10000 Angstroms, such as 5000 Angstroms. The release protection layer 1828 can then be removed after release of the SAC layer 1808.

In block 1760, the SAC layer 1808 is then removed to define an air cavity 1832, as shown in FIG. 18I and FIG. 19I. In some implementations, the SAC layer 1808 is released by exposing the structure to XeF₂ gas or SF₆ plasma, for instance, when the SAC layer 1808 is formed of Mo or a-Si. HF can be used when the SAC layer 1808 is formed of SiON or SiOx. FIG. 19I shows a perspective back view of the resulting resonator structure, with substrate 1804 not shown to better illustrate cavity 1832. The cavity 1832 region is essentially defined by the absence of the SAC layer 1808; thus, the cavity 1832 includes side areas 1819 and a portion underlying the first metal strip 1818 of the resonator.

In some implementations, prior to the release operation of block 1760, a metal interconnect layer can be deposited and patterned outside of the resonator structure to define transmission lines to the first, second, and third metal layers 1816, 1824, and 1825, respectively. AlSi, AlCu, plated Cu, or other appropriate material can be used to form the metal interconnect layer.

The piezoelectric materials that can be used in fabrication of the piezoelectric layers of electromechanical systems resonators and dielectric layers of passive components disclosed herein include, for example, aluminum nitride (AlN), zinc oxide (ZnO), gallium arsenide (GaAs), aluminum gallium arsenide (AlGaAs), gallium nitride (GaN), quartz and other piezoelectric materials such as zinc-sulfide (ZnS), cadmium-sulfide (CdS), lithium tantalite (LiTaO3), lithium niobate (LiNbO3), lead zirconate titanate (PZT), members of the lead lanthanum zirconate titanate (PLZT) family, doped aluminum nitride (AlN:Sc), and combinations thereof. The conductive layers described above may be made of various conductive materials including platinum (Pt), aluminum (Al), molybdenum (Mo), tungsten (W), titanium (Ti), niobium (Nb), ruthenium (Ru), chromium (Cr), doped polycrystalline silicon, doped aluminum gallium arsenide (AlGaAs) compounds, gold (Au), copper (Cu), silver (Ag), tantalum (Ta), cobalt (Co), nickel (Ni), palladium (Pd), silicon germanium (SiGe), doped conductive zinc oxide (ZnO), and combinations thereof. In various implementations, the upper metal electrodes and/or the lower metal electrodes can include the same conductive material(s) or different conductive materials.

The description herein is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

An example of a suitable electromechanical systems (EMS) or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the IMOD. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

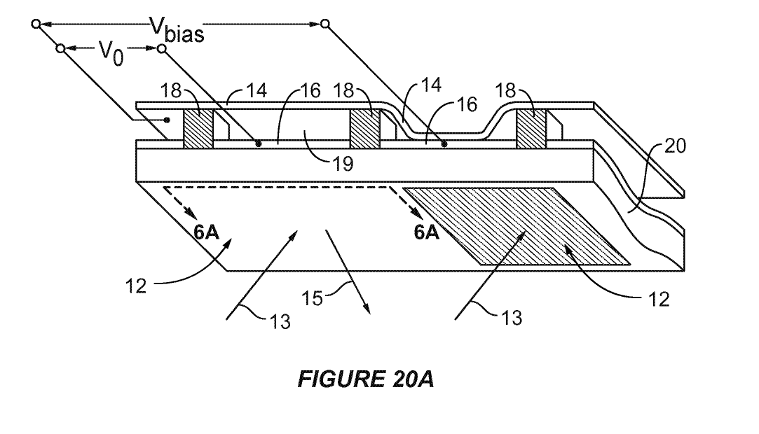

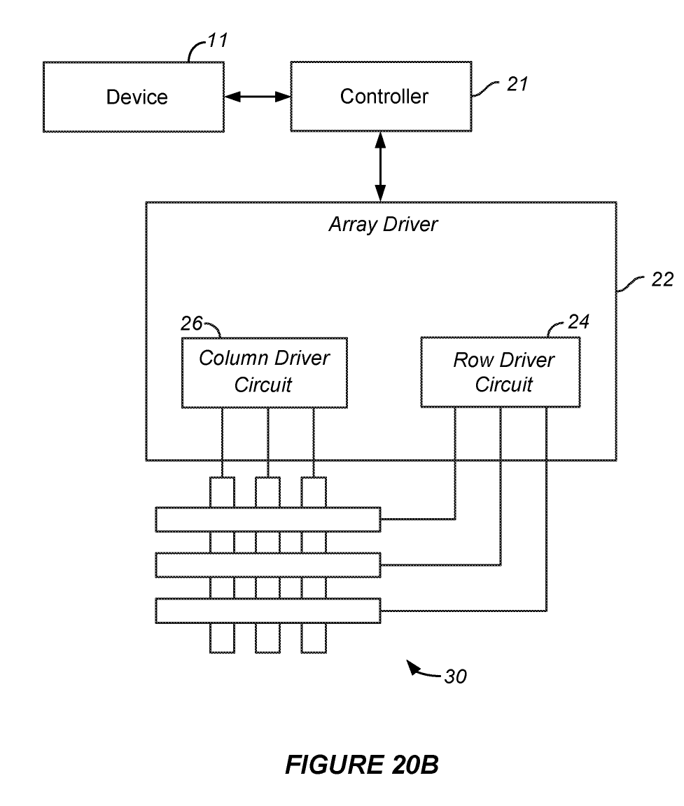

FIG. 20A shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 20A includes two adjacent IMODs 12. In the IMOD 12 on the left (as illustrated), a movable reflective layer 14 is illustrated in a relaxed position at a predetermined distance from an optical stack 16, which includes a partially reflective layer. The voltage V0 applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage Vbias applied across the IMOD 12 on the right is sufficient to maintain the movable reflective layer 14 in the actuated position.

In FIG. 20A, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, including chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (such as the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the separation between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 20A, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 20A. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 20B shows an example of a system block diagram illustrating an electronic device incorporating a 3×3 IMOD display. The electronic device of FIG. 20B represents one implementation in which a combined resonator and passive component(s) device 11 constructed in accordance with the implementations described above with respect to FIGS. 6-19 can be incorporated. The electronic device in which device 11 is incorporated may, for example, form part or all of any of the variety of electrical devices and electromechanical systems devices set forth above, including both display and non-display applications.

Here, the electronic device includes a controller 21, which may include one or more general purpose single- or multi-chip microprocessors such as an ARM®, Pentium®, 8051, MIPS®, Power PC®, or ALPHA®, or special purpose microprocessors such as a digital signal processor, microcontroller, or a programmable gate array. Controller 21 may be configured to execute one or more software modules. In addition to executing an operating system, the controller 21 may be configured to execute one or more software applications, including a web browser, a telephone application, an email program, or any other software application.

The controller 21 is configured to communicate with device 11. The controller 21 also can be configured to communicate with an array driver 22. The array driver 22 can include a row driver circuit 24 and a column driver circuit 26 that provide signals to, e.g., a display array or panel 30. Although FIG. 20B illustrates a 3×3 array of IMODs for the sake of clarity, the display array 30 may contain a very large number of IMODs, and may have a different number of IMODs in rows than in columns, and vice versa. Controller 21 and array driver 22 may sometimes be referred to herein as being “logic devices” and/or part of a “logic system.”

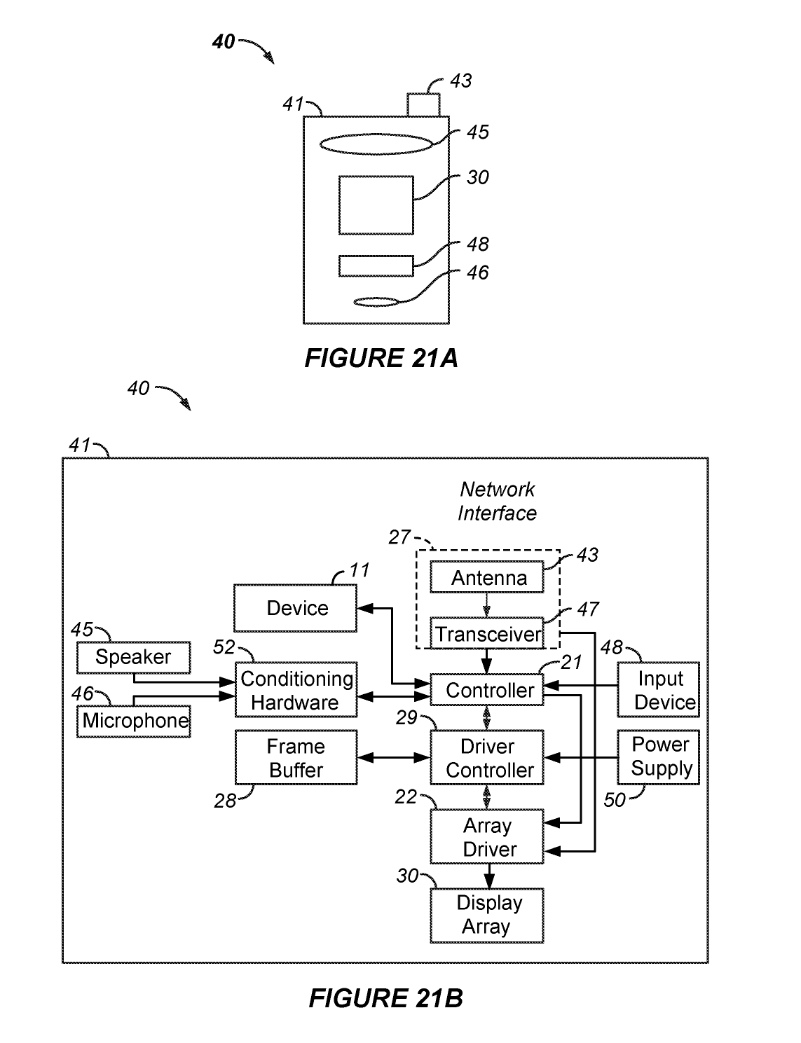

FIGS. 21A and 21B show examples of system block diagrams illustrating a display device 40 that includes a plurality of IMODs. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD display, as described herein.

The components of the display device 40 are schematically illustrated in FIG. 21B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A piezoelectric resonator structure comprising:
a lower conductive layer of electrodes;
a lower piezoelectric layer disposed on the lower conductive layer;
a middle conductive layer of electrodes disposed on the lower piezoelectric layer opposite the lower conductive layer;
an upper piezoelectric layer disposed on the middle conductive layer opposite the lower piezoelectric layer; and
an upper conductive layer of electrodes disposed on the upper piezoelectric layer opposite the middle conductive layer;
wherein:
a first arrangement of the electrodes is located at a first position along a width of the structure and generally aligned along a thickness of the structure, the first arrangement including a first-type drive electrode in the lower conductive layer, a second-type drive electrode in the middle conductive layer, and a first-type drive electrode in the upper conductive layer;
a second arrangement of the electrodes is located at a second position along the width and generally aligned along the thickness, the second arrangement including a second-type drive electrode in the lower conductive layer, a first-type drive electrode in the middle conductive layer, and a second-type drive electrode in the upper conductive layer;
the first-type drive electrodes are coupled to receive a first input signal; and
the second-type drive electrodes are coupled to receive a second input signal.

2. The piezoelectric resonator structure of claim 1, wherein the first arrangement and the second arrangement are periodically repeated at least once along the width such that there are at least two instances of the first arrangement and at least two instances of the second arrangement and such that each instance of the first arrangement is separated by an adjacent instance of the first arrangement by an instance of the second arrangement, and vice versa.

3. The piezoelectric resonator structure of claim 2, wherein a center-to-center distance from each electrode to its closest neighbor electrode along the same conductive layer is substantially equal to half of the acoustic wavelength, λ, of the structure, and wherein a center-to-center distance from each electrode to the next electrode of the same type along the same conductive layer is substantially equal to λ.

4. The piezoelectric resonator structure of claim 1, further comprising a third arrangement of the electrodes located at a third position along the width and generally aligned along the thickness, the third arrangement including a first-type signal electrode in the lower conductive layer, a second-type signal electrode in the middle conductive layer, and a first-type signal electrode in the upper conductive layer.

5. The piezoelectric resonator structure of claim 4, wherein the first-type signal electrodes are coupled to output an output signal.

6. The piezoelectric resonator structure of claim 1, wherein the electrodes in the middle conductive layer in the first and second arrangements each have a width that is substantially greater than that of each of the respective overlying or underlying electrodes of the upper and lower conductive layers.

7. The piezoelectric resonator structure of claim 1, wherein when the first and second input signals are respectively applied to the first-type drive electrodes and the second-type drive electrodes:
a first vertical electric field component is generated between the first-type drive electrode in the lower conductive layer of the first arrangement and the second-type drive electrode in the middle conductive layer of the first arrangement;
a second vertical electric field component is generated between the first-type drive electrode in the upper conductive layer of the first arrangement and the second-type electrode in the middle conductive layer of the first arrangement;
a third vertical electric field component is generated between the second-type drive electrode in the lower conductive layer of the second arrangement and the first-type drive electrode in the middle conductive layer of the second arrangement;
a fourth vertical electric field component is generated between the second-type drive electrode in the upper conductive layer of the second arrangement and the first-type drive electrode in the middle conductive layer of the second arrangement;
a first lateral electric field component is generated between the second-type drive electrode in the middle conductive layer of the first arrangement and the first-type drive electrode in the middle conductive layer of the second arrangement;
the first, the second, the third, the fourth vertical electric field components cause displacement in the upper and lower piezoelectric layers; and
the first lateral electric field component causes displacement in the upper and lower piezoelectric layers.

8. The piezoelectric resonator structure of claim 7, wherein during at least a duration, the first vertical electric field component, the second vertical electric field component, the third vertical electric field component, the fourth vertical electric field component, and the first lateral electric field component are generated simultaneously causing displacements in the upper and lower piezoelectric layers simultaneously.

9. The piezoelectric resonator structure of claim 7, wherein:
the piezoelectric resonator structure further includes a third arrangement of the electrodes located at a third position along the width and generally aligned along the thickness, the third arrangement including a first-type signal electrode in the lower conductive layer, a second-type signal electrode in the middle conductive layer, and a first-type signal electrode in the upper conductive layer;
the first-type signal electrodes are coupled to output an output signal;
the third arrangement of the electrodes is configured to sense displacement resulting from vibrations caused by the first, second, third, and fourth vertical field components and the first lateral field component and to output the output signal based on the sensed displacement.

10. The piezoelectric resonator structure of claim 9, wherein during at least a duration, the first vertical electric field component, the second vertical electric field component, the third vertical electric field component, the fourth vertical electric field component, and the first lateral electric field component are generated simultaneously causing displacements in the upper and lower piezoelectric layers simultaneously.

11. The piezoelectric resonator structure of claim 1, wherein:
each of the upper and lower piezoelectric layers has a thickness d;
the acoustic wavelength associated with a resonate mode of the resonator structure has a value λ;
a ratio of d/λ is approximately 0.1 or larger; and
a frequency of the resonate mode is greater than or equal to 0.1 GHz.

12. The piezoelectric resonator structure of claim 1, wherein the piezoelectric resonator structure is configured as a contour mode resonator and wherein the contour mode resonator supports one or more Lamb wave modes of vibration.

13. The resonator structure of claim 1 further comprising:
one or more tethers coupled to support the layers within a cavity.

14. The resonator structure of claim 1 further comprising:
a display;
a processor configured to communicate with the display, the processor being configured to process image data; and
a memory device configured to communicate with the processor.

15. The structure of claim 14 further comprising:
a driver circuit configured to send at least one signal to the display; and
a controller configured to send at least a portion of the image data to the driver circuit.

16. The structure of claim 14, wherein one or more of the electrodes are coupled to send the image data to the processor.

17. A process for forming a resonator structure, comprising:
forming a lower conductive layer of electrodes;
forming a lower piezoelectric layer over the lower electrode layer;
forming a middle conductive layer of electrodes over the lower piezoelectric layer;
forming an upper piezoelectric layer over the middle conductive layer; and
forming an upper conductive layer of electrodes over the upper piezoelectric layer;
wherein:
a first arrangement of the electrodes is located at a first position along a width of the structure and generally aligned along a thickness of the structure, the first arrangement including a first-type drive electrode in the lower conductive layer, a second-type drive electrode in the middle conductive layer, and a first-type drive electrode in the upper conductive layer;
a second arrangement of the electrodes is located at a second position along the width and generally aligned along the thickness, the second arrangement including a second-type drive electrode in the lower conductive layer, a first-type drive electrode in the middle conductive layer, and a second-type drive electrode in the upper conductive layer;
the first-type drive electrodes are coupled to receive a first input signal; and
the second-type drive electrodes are coupled to receive a second input signal.

18. The process of claim 17, wherein forming the lower conductive layer of electrodes comprises forming the lower conductive layer of electrodes over a sacrificial layer, and wherein the process further comprises:
forming the sacrificial layer on a substrate prior to forming the lower conductive layer of electrodes over the sacrificial layer; and
removing at least a portion of the sacrificial layer to define a cavity such that at least a substantial portion of the lower electrode layer is spaced apart from the substrate.

19. The process of claim 18, wherein removing the portion of the sacrificial layer comprises performing an isotropic release etch on the sacrificial layer.

20. A method comprising:
providing a piezoelectric resonator structure that includes:
a lower conductive layer of electrodes;
a lower piezoelectric layer disposed on the lower conductive layer;
a middle conductive layer of electrodes disposed on the lower piezoelectric layer opposite the lower conductive layer;
an upper piezoelectric layer disposed on the middle conductive layer opposite the lower piezoelectric layer; and
an upper conductive layer of electrodes disposed on the upper piezoelectric layer opposite the middle conductive layer;
wherein:
a first arrangement of the electrodes is located at a first position along a width of the structure and generally aligned along a thickness of the structure, the first arrangement including a first-type drive electrode in the lower conductive layer, a second-type drive electrode in the middle conductive layer, and a first-type drive electrode in the upper conductive layer; and
a second arrangement of the electrodes is located at a second position along the width and generally aligned along the thickness, the second arrangement including a second-type drive electrode in the lower conductive layer, a first-type drive electrode in the middle conductive layer, and a second-type drive electrode in the upper conductive layer;
applying a first input signal to the first-type drive electrodes; and
applying a second input signal to the second-type drive electrodes;
wherein applying the first and second input signals causes one or more modes of vibration in the piezoelectric resonator structure.

21. The method of claim 20, wherein:
the piezoelectric resonator structure further comprises a third arrangement of the electrodes located at a third position along the width and generally aligned along the thickness, the third arrangement including a first-type signal electrode in the lower conductive layer, a second-type signal electrode in the middle conductive layer, and a first-type signal electrode in the upper conductive layer;
the method further comprises:
sensing, using the third arrangement of electrodes, displacements associated with the d₃₃ piezoelectric field component resulting from vibrations caused by vertical and lateral electric field components resulting from the applied first and second input signals; and
outputting an output signal based on the sensing.

22. A resonator structure comprising:
first conductive means of electrodes;
first piezoelectric means including a first piezoelectric material disposed over the first conductive means of electrodes;
second conductive means of electrodes disposed over the first piezoelectric means opposite the first conductive means of electrodes;
second piezoelectric means including a second piezoelectric material disposed over the second conductive means of electrodes opposite the first piezoelectric means; and
third conductive means of electrodes disposed over the second piezoelectric means opposite the second conductive means of electrodes;
first coupling means; and
second coupling means;
wherein:
a first arrangement of the electrodes is located at a first position along a width of the structure and generally aligned along a thickness of the structure, the first arrangement including a first-type drive electrode in the first conductive means, a second-type drive electrode in the second conductive means, and a first-type drive electrode in the third conductive means;
a second arrangement of the electrodes is located at a second position along the width and generally aligned along the thickness, the second arrangement including a second-type drive electrode in the first conductive means, a first-type drive electrode in the second conductive means, and a second-type drive electrode in the third conductive means;
the first-type drive electrodes are coupled to receive a first input signal via the first coupling means; and
the second-type drive electrodes are coupled to receive a second input signal via the second coupling means.

23. The piezoelectric resonator structure of claim 22, wherein the first arrangement and the second arrangement are periodically repeated at least once along the width such that there are at least two instances of the first arrangement and at least two instances of the second arrangement and such that each instance of the first arrangement is separated by an adjacent instance of the first arrangement by an instance of the second arrangement, and vice versa.

24. The piezoelectric resonator structure of claim 23, wherein a center-to-center distance from each electrode to its closest neighbor electrode along the same conductive means of electrodes is substantially equal to half of the acoustic wavelength, λ, of the structure, and wherein a center-to-center distance from each electrode to the next electrode of the same type along the same conductive means of electrodes is substantially equal to λ.

25. The piezoelectric resonator structure of claim 22, further comprising:
a third arrangement of the electrodes located at a third position along the width and generally aligned along the thickness, the third arrangement including a first-type signal electrode in the first conductive means, a second-type signal electrode in the second conductive means, and a first-type signal electrode in the third conductive means; and
third coupling means;
wherein the first-type signal electrodes are coupled to output an output signal via the third coupling means.

26. The piezoelectric resonator structure of claim 22, wherein the electrodes in the second conductive means of electrodes in the first and second arrangements each have a width that is substantially greater than that of each of the respective overlying or underlying electrodes of the third and first conductive means of electrodes.

27. The piezoelectric resonator structure of claim 22, wherein:
each of the first and second piezoelectric means has a thickness d;
the acoustic wavelength associated with a resonate mode of the resonator structure has a value λ;
a ratio of d/λ is approximately 0.1 or larger; and
a frequency of the resonate mode is greater than or equal to 0.1 GHz.
